(19) United States
(12) Patent Application Publication
(10) Pub. No.: US 2024/0213429 A1
(43) Pub. Date: Jun. 27, 2024

(54) CERAMIC SINTERED COMPACT SUBSTRATE, LIGHT-EMITTING DEVICE, AND METHODS FOR MANUFACTURING CERAMIC SINTERED COMPACT SUBSTRATE AND LIGHT-EMITTING DEVICE

(71) Applicant: NICHIA CORPORATION, Anan-shi (JP)

(72) Inventors: Akiko NAGAE, Komatsushima-shi (JP); Masaaki KATSUMATA, Anan-shi (JP)

(73) Assignee: NICHIA CORPORATION, Anan-shi (JP)

(21) Appl. No.: 18/391,651

(22) Filed: Dec. 21, 2023

(30) Foreign Application Priority Data
Dec. 23, 2022 (JP) 2022-207632

(51) Int. Cl. H01L 33/62; H01L 23/00; H05K 3/00; H05K 3/24; H05K 3/40

(52) U.S. Cl. CPC H01L 33/62; H05K 3/002; H05K 3/0023; H05K 3/0029; H05K 3/4061; H01L 24/05; H01L 24/16; H01L 24/81; H01L 24/97; H01L 2224/05644; H01L 2224/05655; H01L 2224/05666; H01L 2224/05669; H01L 2224/05671; H01L 2224/05673; H01L 2224/0568; H01L 2224/05684; H01L 2224/13144; H01L 2224/16227; H01L 2224/81192; H01L 2224/97; H01L 2924/12041; H01L 2933/0066; H05K 3/0052; H05K 3/243; H05K 2203/072; H05K 2203/107

(57) ABSTRACT

A manufacturing method for a ceramic sintered compact substrate including preparing a ceramic substrate, bonding dry films to a first surface and a second surface of the ceramic substrate, performing exposure and development, performing etching or blasting through the dry films formed into a predetermined pattern, forming a first recessed portion recessed relative to a first flat surface portion of the first surface and a second recessed portion recessed relative to a second flat surface portion of the second surface, peeling off the dry films, disposing a metal paste, and firing the metal paste to obtain a metal member. In the method, before the first recessed portion and the second recessed portion are formed, a through hole penetrating through the ceramic substrate is formed , and the metal paste is disposed in the first recessed portion, the second recessed portion, and the through hole.

### CROSS-REFERENCE TO RELATED APPLICATIONS

The present application claims priority under 35 U.S.C. §119 to Japanese Patent Application No. 2022-207632, filed Dec. 23, 2022, the content of which is hereby incorporated by reference in its entirety.

### 1. TECHNICAL FIELD

The present disclosure relates to a ceramic sintered compact substrate, a light-emitting device, and methods for manufacturing the ceramic sintered compact substrate and the light-emitting device.

### 2. DESCRIPTION OF RELATED ART

A resist layer has been formed on a non-conductive base material using a high-molecular substance, fine pattern grooves have been formed using a laser beam, and then blackened conductive patterns have been formed in the fine pattern grooves (see, for example, Patent Application Publication No. 2011-512644). SUMMARY

An embodiment according to the present disclosure provides a ceramic sintered compact substrate having high pattern accuracy, a light-emitting device, and methods for manufacturing the ceramic sintered compact substrate and the light-emitting device.

A method for manufacturing a ceramic sintered compact substrate disclosed in an embodiment includes: preparing a ceramic substrate having a first surface and a second surface opposite to the first surface; bonding a dry film to the first surface of the ceramic substrate; performing, through a mask, exposure and development on the first surface of the ceramic substrate to which the dry film is bonded; etching or blasting the first surface of the ceramic substrate through the dry film formed into a predetermined pattern by performing the exposure and the development; forming a first recessed portion recessed relative to a first flat surface portion of the first surface of the ceramic substrate by performing the etching or blasting; peeling off the dry film from the ceramic substrate; disposing a metal paste in the first recessed portion of the ceramic substrate; and firing the metal paste disposed in the first recessed portion to obtain a metal member. In the method, before the first recessed portion is formed, a through hole penetrating through the ceramic substrate such that the through hole connects the first surface and the second surface of the ceramic substrate is formed at a position to be the first recessed portion, and in the disposing of the metal paste, the metal paste is disposed in the first recessed portion and the through hole.

Another method for manufacturing a ceramic sintered compact substrate disclosed in an embodiment includes: preparing a ceramic substrate having a first surface and a second surface opposite to the first surface; bonding a dry film to each of the first surface and the second surface of the ceramic substrate; performing, through a mask, exposure and development on the first surface and the second surface of the ceramic substrate to which the dry films are bonded; etching or blasting the first surface and the second surface of the ceramic substrate through the dry films formed into a predetermined pattern by performing the exposure and the development; forming a first recessed portion recessed relative to a first flat surface portion of the first surface of the ceramic substrate and a second recessed portion recessed relative to a second flat surface portion of the second surface of the ceramic substrate by performing the etching or blasting; peeling off the dry films from the ceramic substrate; disposing a metal paste in the first recessed portion and the second recessed portion of the ceramic substrate; and firing the metal paste disposed in the first recessed portion and the second recessed portion to obtain a metal member. In the method, before the first recessed portion and the second recessed portion are formed, a through hole penetrating through the ceramic substrate such that the through hole connects the first surface and the second surface of the ceramic substrate is formed at positions to be the first recessed portion and the second recessed portion, and in the disposing of the metal paste, the metal paste is disposed in the first recessed portion, the second recessed portion, and the through hole.

A method for manufacturing a light-emitting device disclosed in an embodiment includes: preparing a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole, and a metal member disposed in the first recessed portion, the second recessed portion, and the through hole, and in which at least one of a connection portion between the through hole and an inner surface defining the first recessed portion and a connection portion between the through hole and an inner surface defining the second recessed portion has roundness in cross-sectional view in a thickness direction of the through hole; and disposing a light-emitting element over the metal member. In the method, in the disposing of the light-emitting element, the metal member and the light-emitting element are directly or indirectly electrically connected to each other.

Another method for manufacturing a light-emitting device disclosed in an embodiment includes: preparing a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and a metal member disposed in the first recessed portion and the through hole, and in which a connection portion between the through hole and an inner surface defining the first recessed portion has roundness in cross-sectional view in a thickness direction of the through hole; and disposing a light-emitting element over the metal member. In the method, in the disposing of the light-emitting element, the metal member and the light-emitting element are directly or indirectly electrically connected with each other.

A ceramic sintered compact substrate disclosed in an embodiment includes: a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole; and a metal member disposed in the first recessed portion and the through hole. In the ceramic sintered compact substrate, a connection portion between the through hole and an inner surface defining the first recessed portion has roundness in cross-sectional view in a thickness direction of the through hole.

A ceramic sintered compact substrate disclosed in an embodiment includes: a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole; and a metal member disposed in the first recessed portion, the second recessed portion, and the through hole. In the ceramic sintered compact substrate, at least one of a connection portion between the through hole and an inner surface defining the first recessed portion and a connection portion between the through hole and an inner surface defining the second recessed portion has roundness in cross-sectional view in a thickness direction of the through hole.

A light-emitting device disclosed in an embodiment includes: a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole, and a metal member disposed in the first recessed portion, the second recessed portion, and the through hole, and in which at least one of a connection portion between the through hole and an inner surface defining the first recessed portion and a connection portion between the through hole and an inner surface defining the second recessed portion has roundness in cross-sectional view in a thickness direction of the through hole; and a light-emitting element that is disposed over the metal member. In the light-emitting device, the light-emitting element is directly or indirectly electrically connected to the metal member.

Another light-emitting device disclosed in an embodiment includes: a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and a metal member disposed in the first recessed portion and the through hole, and in which a connection portion between the through hole and an inner surface defining the first recessed portion has roundness in cross-sectional view in a thickness direction of the through hole; and a light-emitting element that is disposed over the metal member. In the light-emitting device, the light-emitting element is directly or indirectly electrically connected to the metal member.

According to an embodiment of the present disclosure, it is possible to provide a ceramic sintered compact substrate having high pattern accuracy, a light-emitting device, and methods for manufacturing the ceramic sintered compact substrate and the light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view illustrating a ceramic sintered compact substrate according to a first embodiment.

FIG. 1B is a schematic bottom view illustrating the ceramic sintered compact substrate according to the first embodiment.

FIG. 1C is a schematic cross-sectional view illustrating a cross section taken along line IC-IC of FIG. 1A.

FIG. 2 is a partially enlarged photograph showing a cross section of a ceramic sintered compact substrate according to an embodiment.

FIG. 3 is a flowchart showing a method for manufacturing the ceramic sintered compact substrate according to the first embodiment.

FIG. 4 is a schematic plan view illustrating an assembly of ceramic sintered compact substrates before singulation in a method for manufacturing a ceramic sintered compact substrate according to an embodiment.

FIG. 5A is a schematic cross-sectional view illustrating a prepared ceramic substrate in the method for manufacturing the ceramic sintered compact substrate according to the first embodiment.

FIG. 5B is a schematic cross-sectional view illustrating a state in which through holes are formed in the method for manufacturing the ceramic sintered compact substrate according to the first embodiment.

FIG. 5C is a schematic cross-sectional view illustrating a state in which dry films are bonded in the method for manufacturing the ceramic sintered compact substrate according to the first embodiment.

FIG. 5D is a schematic cross-sectional view illustrating a state in which exposure of the dry films is performed in the method for manufacturing the ceramic sintered compact substrate according to the first embodiment.

FIG. 5E is a schematic cross-sectional view illustrating a state in which development of the dry films is performed in the method for manufacturing the ceramic sintered compact substrate according to the first embodiment.

FIG. 5F is a schematic cross-sectional view illustrating an etched or blasted state in the method for manufacturing the ceramic sintered compact substrate according to the first embodiment.

FIG. 5G is a schematic cross-sectional view illustrating a state in which the dry films are peeled off in the method for manufacturing the ceramic sintered compact substrate according to the first embodiment.

FIG. 5H is a schematic cross-sectional view illustrating a state in which a metal paste is disposed in the method for manufacturing the ceramic sintered compact substrate according to the first embodiment.

FIG. 5I is a schematic cross-sectional view illustrating a fired metal member in the method for manufacturing the ceramic sintered compact substrate according to the first embodiment.

FIG. 5J is a schematic cross-sectional view illustrating a state in which the metal member is polished in the method for manufacturing the ceramic sintered compact substrate according to the first embodiment.

FIG. 5K is a schematic cross-sectional view taken along line VK-VK of FIG. 4 illustrating a state in which a plating layer is formed on the metal member in the method for manufacturing the ceramic sintered compact substrate according to the first embodiment.

FIG. 5L is a schematic cross-sectional view illustrating a ceramic sintered compact substrate obtained by singulation in the method for manufacturing the ceramic sintered compact substrate according to the first embodiment.

FIG. 6 is a schematic cross-sectional view illustrating a ceramic sintered compact substrate according to a second embodiment.

FIG. 7 is a flowchart showing a method for manufacturing the ceramic sintered compact substrate according to the second embodiment.

FIG. 8A is a schematic cross-sectional view illustrating an etched or blasted state in the method for manufacturing the ceramic sintered compact substrate according to the second embodiment.

FIG. 8B is a schematic cross-sectional view illustrating a state in which a metal paste is disposed in the method for manufacturing the ceramic sintered compact substrate according to the second embodiment.

FIG. 8C is a schematic cross-sectional view illustrating a fired metal member in the method for manufacturing the ceramic sintered compact substrate according to the second embodiment.

FIG. 8D is a schematic cross-sectional view illustrating a state in which the metal member is polished in the method for manufacturing the ceramic sintered compact substrate according to the second embodiment.

FIG. 8E is a schematic cross-sectional view illustrating a state in which a plating layer is formed on the metal member in the method for manufacturing the ceramic sintered compact substrate according to the second embodiment.

FIG. 8F is a schematic cross-sectional view illustrating a ceramic sintered compact substrate obtained by singulation in the method for manufacturing the ceramic sintered compact substrate according to the second embodiment.

FIG. 9 is a schematic cross-sectional view illustrating a ceramic sintered compact substrate according to a third embodiment.

FIG. 10 is a flowchart showing a method for manufacturing the ceramic sintered compact substrate according to the third embodiment.

FIG. 11A is a schematic cross-sectional view illustrating a state in which development of dry films is performed in the method for manufacturing the ceramic sintered compact substrate according to the third embodiment.

FIG. 11B is a schematic cross-sectional view illustrating a state in which recessed portions are formed with a laser in the method for manufacturing the ceramic sintered compact substrate according to the third embodiment.

FIG. 11C is a schematic cross-sectional view illustrating an etched or blasted state in the method for manufacturing the ceramic sintered compact substrate according to the third embodiment.

FIG. 11D is a schematic cross-sectional view illustrating a state in which a metal paste is disposed in the method for manufacturing the ceramic sintered compact substrate according to the third embodiment.

FIG. 11E is a schematic cross-sectional view illustrating a fired metal member in the method for manufacturing the ceramic sintered compact substrate according to the third embodiment.

FIG. 11F is a schematic cross-sectional view illustrating a state in which the metal member is polished in the method for manufacturing the ceramic sintered compact substrate according to the third embodiment.

FIG. 11G is a schematic cross-sectional view illustrating a state in which a plating layer is formed on the metal member in the method for manufacturing the ceramic sintered compact substrate according to the third embodiment.

FIG. 11H is a schematic cross-sectional view illustrating a ceramic sintered compact substrate obtained by singulation in the method for manufacturing the ceramic sintered compact substrate according to the third embodiment.

FIG. 12A is a schematic cross-sectional view illustrating a first modification of the ceramic sintered compact substrate.

FIG. 12B is a schematic cross-sectional view illustrating a second modification of the ceramic sintered compact substrate.

FIG. 13A is a schematic cross-sectional view illustrating a third modification of the ceramic sintered compact substrate.

FIG. 13B is a schematic cross-sectional view illustrating a fourth modification of the ceramic sintered compact substrate.

FIG. 14 is a flowchart showing a method for manufacturing the ceramic sintered compact substrate of the third modification.

FIG. 15A is a schematic cross-sectional view illustrating a state in which dry films are bonded in the method for manufacturing the ceramic sintered compact substrate of the third modification.

FIG. 15B is a schematic cross-sectional view illustrating a state in which patterns are formed with respect to dry films with a laser in the method for manufacturing the ceramic sintered compact substrate of the third modification.

FIG. 15C is a schematic cross-sectional view illustrating an etched or blasted state in the method for manufacturing the ceramic sintered compact substrate of the third modification.

FIG. 16 is a schematic cross-sectional view illustrating a fifth modification of the ceramic sintered compact substrate.

FIG. 17 is a flowchart showing a modification of the method for manufacturing the ceramic sintered compact substrate according to the first embodiment.

FIG. 18A is a schematic cross-sectional view illustrating a state in which through holes are formed in the modification of the method for manufacturing the ceramic sintered compact substrate according to the first embodiment.

FIG. 18B is a schematic cross-sectional view illustrating a state in which adhesive layers are disposed in the modification of the method for manufacturing the ceramic sintered compact substrate according to the first embodiment.

FIG. 18C is a schematic cross-sectional view illustrating a state in which dry films are bonded in the modification of the method for manufacturing the ceramic sintered compact substrate according to the first embodiment.

FIG. 18D is a schematic cross-sectional view illustrating a state in which exposure of the dry films is performed in the modification of the method for manufacturing the ceramic sintered compact substrate according to the first embodiment.

FIG. 18E is a schematic cross-sectional view illustrating a state in which development of the dry films is performed in the modification of the method for manufacturing the ceramic sintered compact substrate according to the first embodiment.

FIG. 18F is a schematic cross-sectional view illustrating an etched or blasted state in the modification of the method for manufacturing the ceramic sintered compact substrate according to the first embodiment.

FIG. 18G is a schematic cross-sectional view illustrating a state in which the dry films and the adhesive layers are peeled off in the modification of the method for manufacturing the ceramic sintered compact substrate according to the first embodiment.

FIG. 19 is a flowchart showing a modification of the method for manufacturing the ceramic sintered compact substrate according to the second embodiment.

FIG. 20A is a schematic cross-sectional view illustrating an etched or blasted state in the modification of the method for manufacturing the ceramic sintered compact substrate according to the second embodiment.

FIG. 20B is a schematic cross-sectional view illustrating a state in which a metal paste is disposed in the modification of the method for manufacturing the ceramic sintered compact substrate according to the second embodiment.

FIG. 20C is a schematic cross-sectional view illustrating a fired metal member in the modification of the method for manufacturing the ceramic sintered compact substrate according to the second embodiment.

FIG. 20D is a schematic cross-sectional view illustrating a state in which the metal member is polished in the modification of the method for manufacturing the ceramic sintered compact substrate according to the second embodiment.

FIG. 21A is a schematic plan view illustrating a light-emitting device according to an embodiment.

FIG. 21B is a schematic cross-sectional view illustrating a cross section taken along line XXIB-XXIB of FIG. 21A.

FIG. 22A is a schematic plan view illustrating a light-emitting element of a light-emitting device according to an embodiment.

FIG. 22B is a schematic bottom view illustrating the light-emitting element of the light-emitting device according to the embodiment.

FIG. 23 is a flowchart showing a method for manufacturing a light-emitting device according to an embodiment.

FIG. 24 is a schematic plan view illustrating an assembly of light-emitting devices before singulation in the method for manufacturing the light-emitting device according to the embodiment.

FIG. 25A is a schematic cross-sectional view illustrating an assembly of prepared ceramic sintered compact substrates in the method for manufacturing the light-emitting device according to the embodiment.

FIG. 25B is a schematic cross-sectional view illustrating a state in which conductive members are disposed in the method for manufacturing the light-emitting device according to the embodiment.

FIG. 25C is a schematic cross-sectional view illustrating a state in which a light-emitting element is disposed in the method for manufacturing the light-emitting device according to the embodiment.

FIG. 25D is a schematic cross-sectional view illustrating a state in which a covering member is disposed in the method for manufacturing the light-emitting device according to the embodiment.

FIG. 25E is a schematic cross-sectional view illustrating a light-emitting device obtained by singulation in the method for manufacturing the light-emitting device according to the embodiment.

FIG. 26A is a schematic cross-sectional view illustrating a first modification of the light-emitting device.

FIG. 26B is a schematic cross-sectional view illustrating a second modification of the light-emitting device.

### DETAILED DESCRIPTION

### Description of Embodiments

Embodiments according to the present disclosure will be described below with reference to the drawings. However, the embodiments described below are merely intended to embody the technical concept according to the present disclosure, and the invention is not limited to the following description unless otherwise specified. The content described in one embodiment can also be applied to another embodiment or modification. The drawings schematically illustrate embodiments, and in order to clarify the description, scales, intervals, positional relationships, and the like of the members may be exaggerated, illustration of a part of the members may be omitted, or an end view illustrating only a cut surface may be used as a cross-sectional view. Directions illustrated in the drawings indicate relative positions between constitution components and are not intended to indicate absolute positions. Members having the same names and reference signs, as a rule, represent the same members or members of the same quality, and detailed description thereof is omitted as appropriate. In the embodiments, “covering” includes not only a case of covering by direct contact but also a case of indirectly covering, for example, via another member.

### Ceramic Sintered Compact Substrate According to First Embodiment

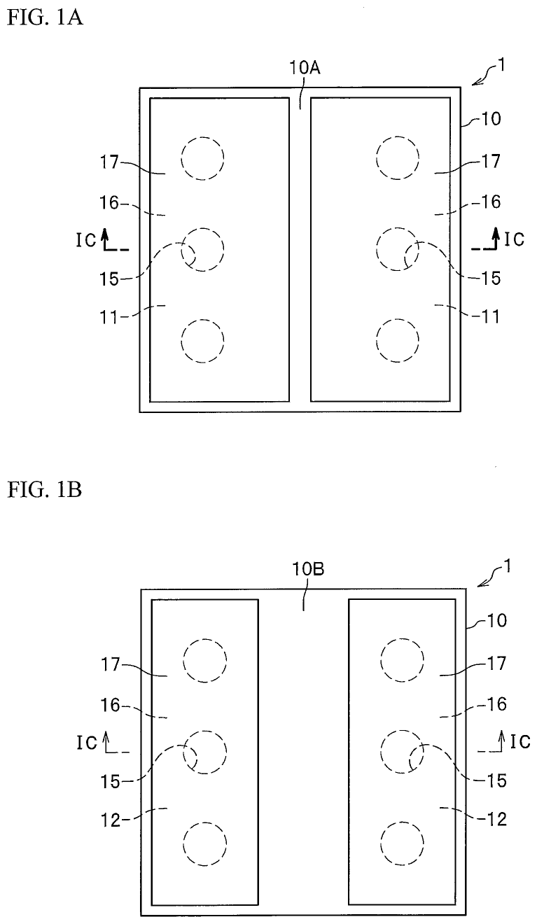

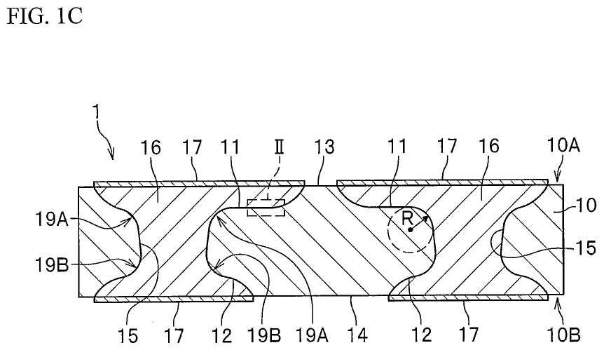

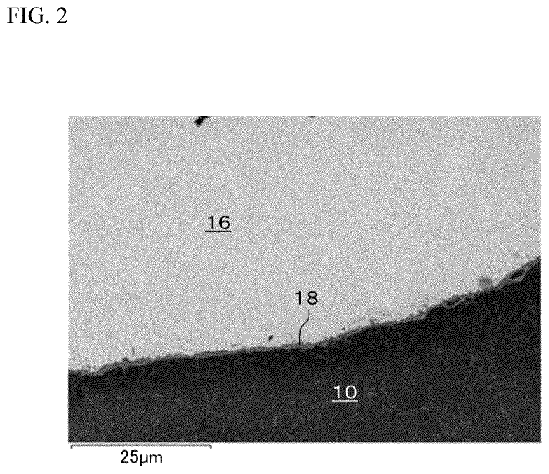

A ceramic sintered compact substrate 1 according to the first embodiment will be described with reference to FIGS. 1A to 2. FIG. 1A is a schematic plan view illustrating the ceramic sintered compact substrate 1. FIG. 1B is a schematic bottom view illustrating the ceramic sintered compact substrate 1. FIG. 1C is a schematic cross-sectional view illustrating a cross section taken along line IC-IC of FIG. 1A. FIG. 2 is a partially enlarged photograph showing a cross section of the ceramic sintered compact substrate 1.

The ceramic sintered compact substrate 1 includes a ceramic substrate 10 and a metal member 16. The ceramic substrate 10 has a first surface 10A and a second surface 10B opposite to the first surface 10A, is provided with a through hole 15 penetrating therethrough connecting the first surface 10A and the second surface 10B, and is provided with, in the first surface 10A, a first recessed portion 11 being larger in hole diameter than the through hole 15 and connected to the through hole 15, and, in the second surface 10B, a second recessed portion 12 being larger in hole diameter than the through hole 15 and connected to the through hole 15. The metal member 16 is disposed in the first recessed portion 11, the second recessed portion 12, and the through hole 15. In cross-sectional view in the thickness direction of the through hole 15, at least one of a connection portion between the through hole 15 and the inner surface defining the first recessed portion 11 and a connection portion between the through hole 15 and the inner surface defining the second recessed portion 12 is rounded. Here, the ceramic sintered compact substrate 1 further includes a plating layer 17 that covers the metal member 16 exposed from the ceramic substrate 10. Each component of the ceramic sintered compact substrate 1 is described below. The ceramic sintered compact substrate refers to what is made by disposing and firing a metal paste in the through hole existing in the ceramic substrate.

### Ceramic Substrate

The ceramic substrate 10 is an insulating member serving as a base on which the metal member 16 is disposed. The ceramic substrate is fired and molded, and is not one in a softened state before firing. The ceramic substrate can be molded by firing a ceramic, or a commercially available product or the like can be used. The ceramic substrate 10 has the first surface 10A and the second surface 10B opposite to the first surface 10A. The first surface 10A includes a first flat surface portion 13 and two first recessed portions 11 recessed relative to the first flat surface portion 13, and the second surface 10B includes a second flat surface portion 14 and two second recessed portions 12 recessed relative to the second flat surface portion 14. Each of the first flat surface portion 13 and the second flat surface portion 14 is a flat surface and constitutes a part of an outer surface of the ceramic sintered compact substrate 1.

Here, the first recessed portion 11 and the second recessed portion 12 have a rectangular shape in plan view, and have a long direction and a short direction. Two first recessed portions 11 and two second recessed portions 12 are disposed in the short direction, and the first recessed portions 11 and the second recessed portions 12 are disposed facing each other. The first recessed portion 11 and the second recessed portion 12 can have round corners in plan view, or the entire ends in the long direction of the first recessed portion 11 and the second recessed portion 12 can be curved.

The first recessed portion 11 and the second recessed portion 12 each have an inner lateral surface in the plate thickness direction that is a curved surface, and a part of a bottom surface defining the corresponding recessed portion continuous with the corresponding through hole 15 that is a flat surface. In cross-sectional view in the plate thickness direction of the ceramic substrate 10, the first recessed portion 11 and the second recessed portion 12 are each curved except for a flat surface of a part of a bottom surface defining the corresponding recessed portion that is on the central side toward the through hole 15. The first recessed portion 11 and the second recessed portion 12 can each have a curved bottom surface defining the corresponding recessed portion continuous to the corresponding through hole 15 from the inner lateral surface. For example, in cross-sectional view in the thickness direction of the ceramic sintered compact substrate 1, the first recessed portion 11 and the second recessed portion 12 can be curved.

The inner surfaces defining the first recessed portion 11 and the second recessed portion 12 are preferably roughened. The roughening can reduce peeling of the metal member 16 disposed in the first recessed portion 11 and the second recessed portion 12. An arithmetic mean roughness Ra of the inner surface defining the first recessed portion 11 and the inner surface defining the second recessed portion 12 can be, for example, in a range from 200 nm to 2 μm, and is preferably in a range from 300 nm to 800 nm. The arithmetic mean roughness Ra can be measured in accordance with JIS B 0601 using a stylus type surface roughness meter (e.g., SE 3500 manufactured by Kosaka Laboratory Ltd.) equipped with a diamond stylus having a tip radius r of curvature of 2 μm.

The hole diameter of the first recessed portion 11 is a diameter of a boundary between the first recessed portion 11 and the first flat surface portion 13, and the hole diameter of the second recessed portion 12 is the diameter of a boundary between the second recessed portion 12 and the second flat surface portion 14. In a case in which the shape of each of the first recessed portion 11 and the second recessed portion 12 in plan view is rectangular, the hole diameter refers to the length of a diagonal line. Furthermore, the hole diameter of the first recessed portion 11 is larger than the hole diameter of the through hole 15 on the first surface 10A side, and the hole diameter of the second recessed portion 12 is larger than the hole diameter of the through hole 15 on the second surface 10B side.

The ceramic substrate 10 includes the through hole 15 penetrating therethrough connecting the first surface 10A and the second surface 10B. The through hole 15 is connected to the first recessed portion 11 and the second recessed portion 12 in the first recessed portion 11 and the second recessed portion 12.

Here, as an example, three through holes 15 are disposed side by side in the long direction on each of the bottom surfaces defining the recessed portions of the first recessed portion 11 and the second recessed portion 12. The three through holes 15 are positioned at the center in the short direction of the second recessed portion 12 in plan view, and are positioned closer to the outer side of the first recessed portion 11. The through hole 15 has a circular shape in plan view, with a diameter decreasing from the first surface 10A side toward the second surface 10B side. The diameter of the through hole 15 can be, for example, in a range from 0.05 mm to 0.5 mm.

In cross-sectional view in the thickness direction of the ceramic substrate 10 in which the through hole 15 is provided, a connection portion 19A between the through hole 15 and the inner surface defining the first recessed portion 11 and a connection portion 19B between the through hole 15 and the inner surface defining the second recessed portion 12 are rounded. This roundness corresponds to an arc having a radius R in a range from 2 μm to 110 μm. The roundness is preferably formed in an annular shape along an opening of the through hole 15 in plan view.

The material of the ceramic substrate 10 is preferably a ceramic having a high thermal conductivity from the viewpoint of heat dissipation, and for example, nitride-based ceramics such as silicon nitride, aluminum nitride, and boron nitride are preferable, but oxide-based ceramics such as aluminum oxide, silicon oxide, calcium oxide, and magnesium oxide can be used. The through hole 15 can be formed by laser processing, machining, or the like.

### Metal Member

The metal member 16 is a member serving as an electrical wiring line in the ceramic sintered compact substrate 1. The metal member 16 is disposed so as to fill the first recessed portion 11, the second recessed portion 12, and the through hole 15. The metal member 16 is disposed so as to be flush with the first flat surface portion 13 on the first surface 10A side of the ceramic substrate 10 and be flush with the second flat surface portion 14 on the second surface 10B side of the ceramic substrate 10. In cross-sectional view in the thickness direction of the ceramic substrate 10, the metal member 16 disposed in the first recessed portion 11 and the second recessed portion 12 is flush with the first flat surface portion 13 of the first surface 10A and the second flat surface portion 14 of the second surface 10B of the ceramic substrate 10.

The metal member 16 is mainly composed of, for example, a metal containing at least one selected from Cu, Cr, Ni, Ag, Al, Zn, Sn, and an Ag—Cu alloy.

The metal member 16 preferably further contains an active metal element such as Ti, Ce, Zr, or Mg.

As shown in FIG. 2 as an example, the ceramic sintered compact substrate 1 includes a metal compound layer 18 at a contact portion between the metal member 16 and the ceramic substrate 10. The metal compound layer 18 is a layer containing a large amount of a compound of an active metal element contained in the metal member 16 and a nonmetallic inorganic element contained in the ceramic substrate 10, for example, titanium nitride. While illustration of the metal compound layer 18 is omitted in drawings other than FIG. 2, the metal compound layer 18 is disposed at a contact portion between the metal member 16 and the ceramic substrate 10 in the present disclosure.

### Plating Layer

The ceramic sintered compact substrate 1 can include the plating layer 17. The plating layer 17 is a metal layer covering the metal member 16 exposed from the ceramic substrate 10. The plating layer 17 reduces oxidation and increases reflectance of the metal member 16. The region where the metal member 16 is disposed protrudes from the first flat surface portion 13 and the second flat surface portion 14 by the thickness of the plating layer 17.

Through the plating layer 17, connection between an external circuit component, a wiring line, or the like and the metal member 16 can be improved. The plating layer 17 can be, for example, three-layer plating of nickel, palladium, and gold or two-layer plating of nickel and gold from the metal member 16 side.

In the ceramic sintered compact substrate 1 having the above configuration, the metal member 16 is embedded in the first recessed portion 11 and the second recessed portion 12, whereby the pattern accuracy can be increased and the heat dissipation can be improved. The surfaces of the first recessed portion 11 and the second recessed portion 12 are roughened and the metal compound layer 18 is provided between the metal member 16 and the ceramic substrate 10; thus, peeling of the metal member 16 can be reduced.

In the ceramic sintered compact substrate 1, since the connection portions between the inner lateral surfaces defining the first recessed portion 11 and the second recessed portion 12 and the bottom surfaces defining the recessed portions and the connection portions between the through hole 15 and the bottom surfaces defining the recessed portions are curved, concentration of stress can be reduced, and reliability can be improved.

Only one of the connection portion between the through hole 15 and the inner surface defining the first recessed portion 11 and the connection portion between the through hole 15 and the inner surface defining the second recessed portion 12 can be rounded in cross-sectional view in the thickness direction of the through hole 15. The diameter of the through hole 15 can be the same from the first surface 10A side to the second surface 10B side, or can increase from the first surface 10A side toward the second surface 10B side. The through hole 15 can have a hand drum shape in which the diameter is reduced at a center portion in the thickness direction.

The ceramic sintered compact substrate 1 preferably has an arithmetic mean roughness Ra in a range from 200 nm to 2 μm, and only one or both of the inner surface defining the first recessed portion 11 and the inner surface defining the second recessed portion 12 can have the roughness.

In cross-sectional view in the thickness direction of the ceramic sintered compact substrate 1, only one or both of the first recessed portion 11 and the second recessed portion 12 can include a connection portion that is curved. In cross-sectional view in the thickness direction of the ceramic sintered compact substrate 1, only one of the first recessed portion 11 and the second recessed portion 12 can be curved.

### Method for Manufacturing Ceramic Sintered Compact Substrate According to First Embodiment

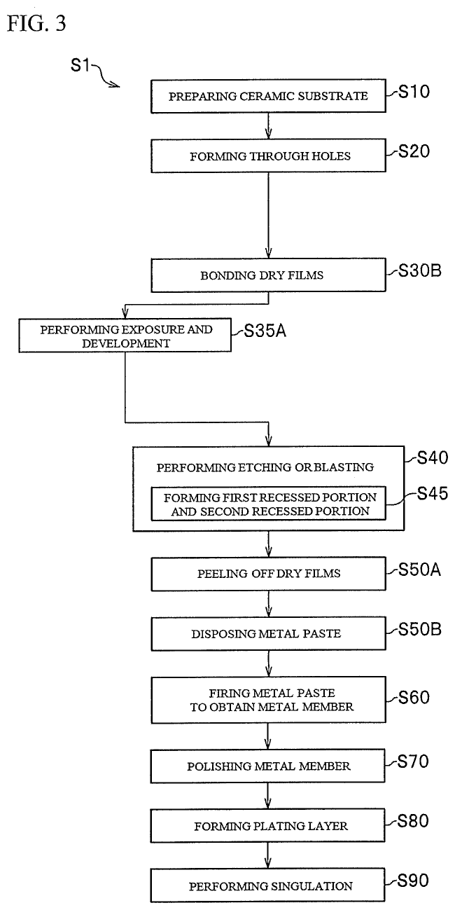

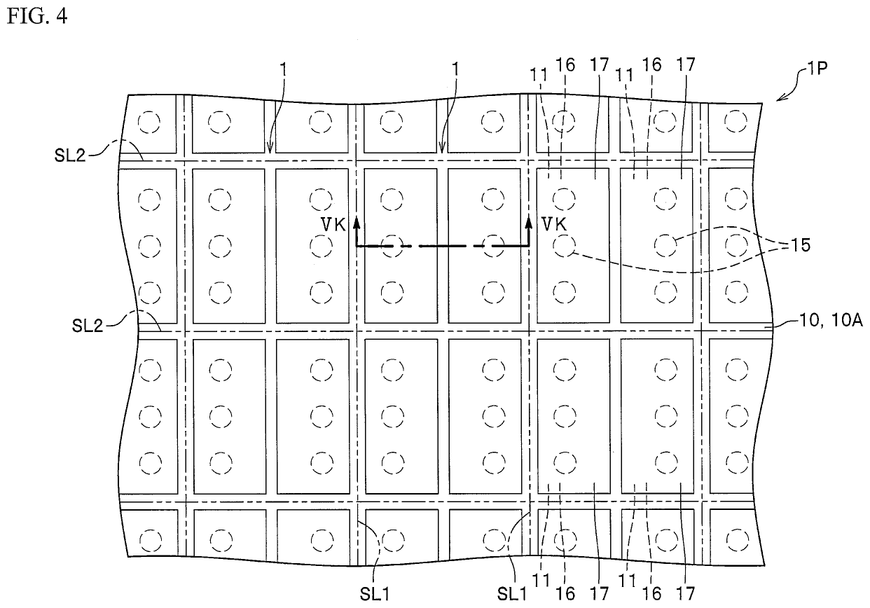

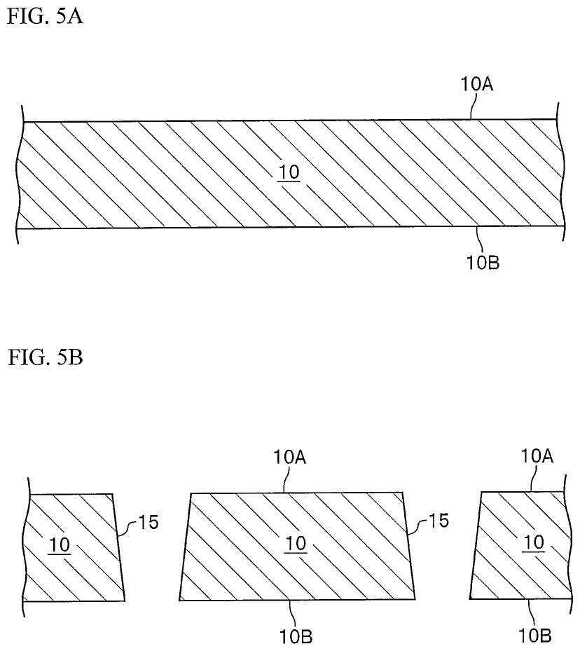

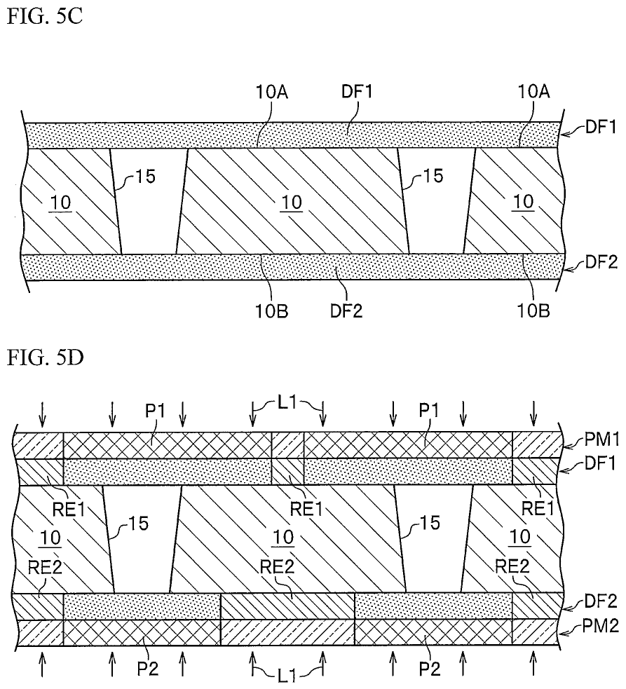

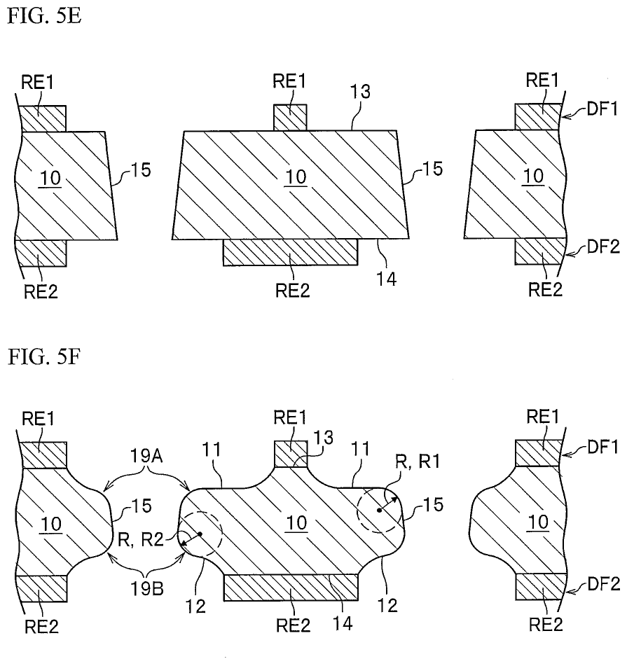

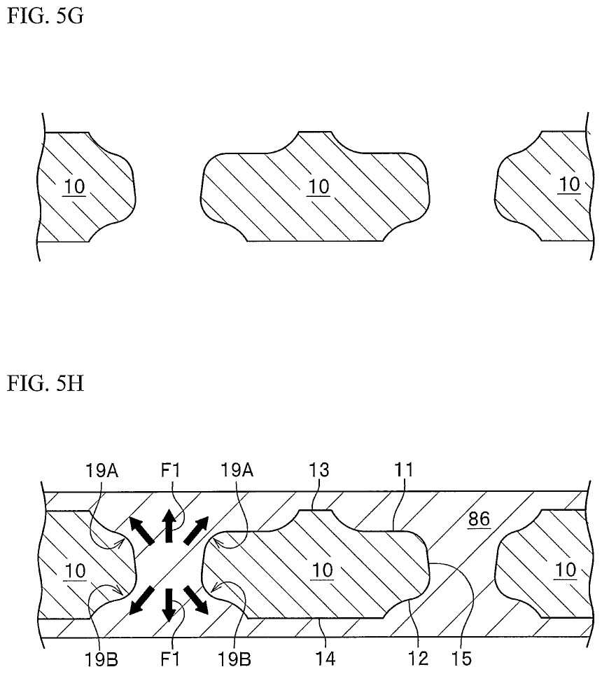

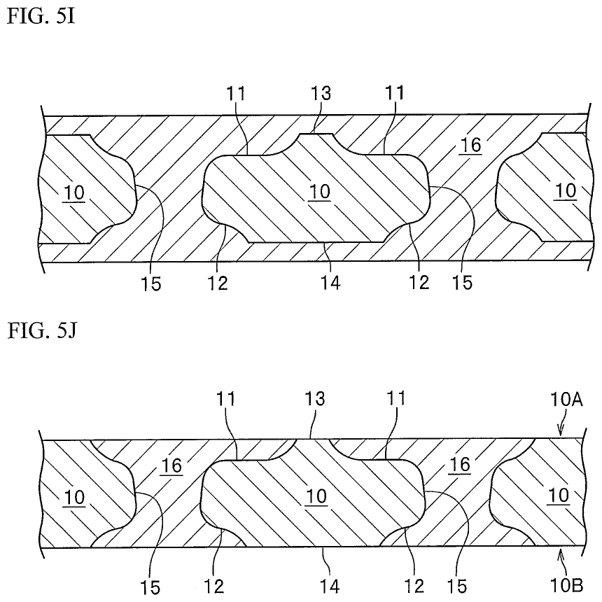

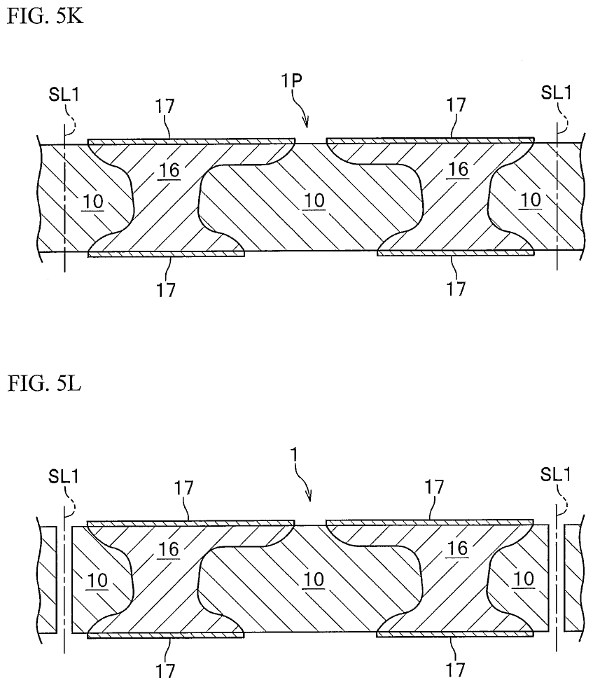

Subsequently, a manufacturing method S1 for the ceramic sintered compact substrate 1 according to the first embodiment will be described with reference to FIGS. 3 to 5L. FIG. 3 is a flowchart showing the manufacturing method S1 for the ceramic sintered compact substrate. FIG. 4 is a schematic plan view illustrating an assembly 1P of the ceramic sintered compact substrates 1 before singulation. FIG. 5A is a schematic cross-sectional view illustrating the ceramic substrate 10 having been prepared. FIG. 5B is a schematic cross-sectional view illustrating a state in which the through holes 15 are formed. FIG. 5C is a schematic cross-sectional view illustrating a state in which dry films DF1 and DF2 are bonded. FIG. 5D is a schematic cross-sectional view illustrating a state in which exposure of the dry films DF1 and DF2 is performed. FIG. 5E is a schematic cross-sectional view illustrating a state in which development of the dry films DF1 and DF2 is performed. FIG. 5F is a schematic cross-sectional view illustrating an etched or blasted state. FIG. 5G is a schematic cross-sectional view illustrating a state in which the dry films DF1 and DF2 are peeled off. FIG. 5H is a schematic cross-sectional view illustrating a state in which a metal paste 86 is disposed. FIG. 5I is a schematic cross-sectional view illustrating the metal member 16 obtained by firing. FIG. 5J is a schematic cross-sectional view illustrating a state in which the metal member 16 is polished. FIG. 5K is a schematic cross-sectional view illustrating a state in which the plating layer 17 is formed on the metal member 16. FIG. 5L is a schematic cross-sectional view illustrating the ceramic sintered compact substrate 1 obtained by singulation.

The manufacturing method S1 for the ceramic sintered compact substrate includes: S10 of preparing the ceramic substrate 10 having the first surface 10A and the second surface 10B opposite to the first surface 10A; S30B of bonding dry films to the first surface 10A and the second surface 10B of the ceramic substrate 10; S35A of performing, through a mask, exposure and development on the first surface 10A and the second surface 10B of the ceramic substrate 10 to which the dry films are bonded; S40 of etching or blasting the first surface 10A and the second surface 10B of the ceramic substrate 10 through the dry films formed into a predetermined pattern by S35A of performing the exposure and the development; S45 of forming the first recessed portion 11 recessed relative to the first flat surface portion 13 of the first surface 10A of the ceramic substrate 10 and the second recessed portion 12 recessed relative to the second flat surface portion 14 of the second surface 10B of the ceramic substrate 10 by S40 of etching or blasting the first surface 10A and the second surface 10B; S50A of peeling off the dry films from the ceramic substrate 10; S50B of disposing the metal paste 86 in the first recessed portion 11 and the second recessed portion 12 of the ceramic substrate 10; and S60 of firing the metal paste 86 disposed in the first recessed portion 11 and the second recessed portion 12 to obtain the metal member 16. Before the first recessed portion 11 and the second recessed portion 12 are formed, the through hole 15 penetrating through the ceramic substrate 10 such that it connects the first surface 10A and the second surface 10B is formed at positions to be the first recessed portion 11 and the second recessed portion 12, and in S50B of disposing the metal paste, the metal paste 86 is disposed in the first recessed portion 11, the second recessed portion 12, and the through hole 15. Here, after S60 of firing the metal paste 86 to obtain the metal member 16, S70 of polishing the metal member, S80 of forming the plating layer 17, and S90 of performing singulation can be further included. Each configuration of the manufacturing method S1 is described below.

In the description of the manufacturing method S1, the assembly 1P in which a plurality of the ceramic sintered compact substrates 1 are aligned in the row direction and the column direction is manufactured. By cutting along cutting lines SL1 and SL2, it is possible to turn the assembly 1P into the ceramic sintered compact substrate 1. The same applies to the method for manufacturing the ceramic sintered compact substrate according to the second and third embodiments, the method for manufacturing the light-emitting device, and modifications thereof.

### Preparing Ceramic Substrate

In S10 of preparing the ceramic substrate, the ceramic substrate 10 is prepared. The ceramic substrate 10 is a plate-like member having the first surface 10A and the second surface 10B opposite to the first surface 10A. The thickness of the ceramic substrate 10 is preferably, for example, in a range from 0.08 mm to 2 mm.

### Forming Through Hole

In S20 of forming the through hole, the through hole 15 penetrating through the ceramic substrate 10 such that it connects the first surface 10A and the second surface 10B is formed. Here, the through hole 15 is formed before the dry films DF1 and DF2 are bonded.

At least one through hole 15 is formed between the first recessed portion 11 and the second recessed portion 12 at positions facing each other. Here, each of the first recessed portion 11 and the second recessed portion 12 has three through holes 15.

The through hole 15 can be formed by, for example, a CO₂ laser. By emitting the CO₂ laser from the first surface 10A side, it is possible to form the through hole 15 such that it has a diameter decreasing from the first surface 10A toward the second surface 10B. By emitting the CO₂ laser from both the first surface 10A side and the second surface 10B side, it is possible to form the through hole 15 such that it has a hole diameter at the center portion in the plate thickness direction becoming smaller than the opening diameter of the first surface 10A and the opening diameter of the second surface 10B. The through hole 15 can have the same diameter from the first surface 10A to the second surface 10B. The through hole 15 can be formed by UV laser, drilling, punching, or the like. The diameter of the through hole 15 is preferably, for example, in a range from 0.05 mm to 0.5 mm.

### Bonding Dry Films

In S30B of bonding dry films, the dry film DF1 is bonded to the first surface 10A of the ceramic substrate 10, and the dry film DF2 is bonded to the second surface 10B of the ceramic substrate 10. The dry films DF1 and DF2 are sheet-shaped photoresists. Here, those with regions that are hardened when exposed are used.

### Performing Exposure and Development

In S35A of performing exposure and development, exposure and development of the dry films DF1 and DF2 are performed. Before the exposure, masks PM1 and PM2 are attached to the dry films DF1 and DF2, respectively, in an overlapping manner. The mask PM1 has a light-shielding pattern P1 in a region where the first recessed portion 11 is formed. The mask PM2 has a light-shielding pattern P2 in a region where the second recessed portion 12 is formed.

Subsequently, light L1 is emitted to perform exposure. The light L1 is, for example, ultraviolet light. Regions other than the light-shielding patterns P1 and P2 transmit the light L1, and the dry films DF1 and DF2 at the positions of the regions are hardened. In the subsequent development, the masks PM1 and PM2 are removed, and unhardened portions of the dry films DF1 and DF2 are dissolved and removed with an alkaline aqueous solution or the like. The hardened portions are not dissolved and not removed but remain, and resists RE1 and RE2 are formed.

### Performing Etching or Blasting

In S40 of performing etching or blasting, the first surface 10A and the second surface 10B of the ceramic substrate 10 are etched or blasted with the dry films (the resists RE1 and RE2) formed into a predetermined pattern as resists.

### Forming First Recessed Portion and Second Recessed Portion

In S45 of forming the first recessed portion and the second recessed portion, the first recessed portion 11 recessed relative to the first flat surface portion 13 of the first surface 10A of the ceramic substrate 10 and the second recessed portion 12 recessed relative to the second flat surface portion 14 of the second surface 10B of the ceramic substrate 10 are formed.

By forming the first recessed portion 11 and the second recessed portion 12 by performing etching or blasting, it is possible to form the inner lateral surfaces defining the first recessed portion 11 and the second recessed portion 12 into a curved shape.

By performing etching or blasting, it is possible to form the connection portion 19A between the through hole 15 and the bottom surface defining the recess portion in the first recess portion 11 and the connection portion 19B between the through hole 15 and the bottom surface defining the recess portion in the second recess portion 12 into a rounded shape in cross-sectional view. Here, this roundness corresponds to an arc having a radius R in a range from 2 μm to 110 μm. A radius R1 of the roundness of the connection portion 19A and a radius R2 of the roundness of the connection portion 19B can be the same or different.

Only either of etching or blasting needs to be performed, and by whichever of these, it is possible to form the first recessed portion 11 and the second recessed portion 12 having curved surfaces and including the connection portions 19A and 19B with the through hole 15 that have rounded shapes in cross-sectional view.

The bottom surfaces defining the recessed portions of the first recessed portion 11 and the second recessed portion 12 in cross-sectional view can partially have flat portions, and the flat portions can be inclined surfaces continuous with the connection portions 19A and 19B.

As the etching, wet etching or dry etching can be performed, and wet etching is preferable. In the wet etching, by performing etching using an acidic or alkaline chemical such as HF, NH₄F, KOH, NaOH, or CsOH, it is possible to form the roundness of the connection portions of the curved first recessed portion 11, the curved second recessed portion 12, and the through hole 15.

In the blasting, abrasive grains are caused to collide with each of the first surface 10A and the second surface 10B from a perpendicular direction, whereby the ceramic substrate 10 is polished or ground, and the curved shape and the roundness of the connection portions can be formed.

### Peeling Off of Dry Films

In S50A of peeling off the dry films, the dry films DF1 and DF2 are peeled off from the ceramic substrate 10. That is, after etching or blasting is performed, the resists RE1 and RE2 are removed.

### Disposing Metal Paste

In S50B of disposing the metal paste, the metal paste 86 is disposed in the first recessed portion 11 and the second recessed portion 12 of the ceramic substrate 10. The metal paste 86 is fired to become the metal member 16.

The metal paste 86 is a member having fluidity, and can be provided by being applied in close contact with the surfaces of the through hole 15, the first recessed portion 11, and the second recessed portion 12. Here, the metal paste 86 is filled in the through hole 15, the first recessed portion 11, and the second recessed portion 12, and further applied to the first flat surface portion 13 and the second flat surface portion 14 so as not to cause unevenness on the surface.

The metal paste 86 can contain at least one selected from Cu, Cr, Ni, Ag, Al, Zn, Sn, and an Ag—Cu alloy. Among them, an Ag—Cu alloy that can be fired at a relatively low temperature, for example, in a range from 780° C. to 850° C. is preferable. Cu or Ag having high electrical conductivity can be used.

The metal paste 86 contains at least active metal powder. The active metal powder can be at least one selected from TiH₂, CeH₂, ZrH₂, and MgH₂. Among them, TiH₂is preferable. By containing TiH₂, the metal paste 86 reacts with nitrogen contained in the ceramic substrate 10 and a metal compound layer is formed as a reaction layer such as TiN at the interface with the ceramic substrate 10. This improves adhesion between the metal member 16, which is a conductive via, and the ceramic substrate 10, and the metal member 16 firmly adheres to the through hole 15.

The metal paste 86 can contain an organic binder. The viscosity of the metal paste 86 can be adjusted depending on the type and amount of the organic binder. The organic binder can be, for example, a solvent generally used as a conductive paste or a resin material such as acrylic, epoxy, urethane, ethyl cellulose, silicone, phenol, polyimide, polyurethane, melamine, or urea. The organic binder is decomposed by firing described later, evaporated, and removed.

The metal paste 86 can contain a plurality of inorganic fillers other than metals. By containing the inorganic fillers, it is possible to reduce volume shrinkage during sintering of the metal paste 86. As the inorganic fillers, for example, AlN, Si₃N₄, or the like can be used.

When expressed in weight percentage, the metal paste 86 preferably contains, for example, 60% or more and 99% or less of an Ag—Cu alloy in which a mixing ratio of Ag and Cu is 72:28, 0.5% or more and 10% or less of TiH2 as active metal powder, 0.1% or more and 10% or less of an organic binder, and 1% or more and 20% or less of an inorganic filler.

### Firing Metal Paste to Obtain Metal Member

In S60 of firing the metal paste to obtain a metal member, the metal paste 86 is disposed in the through hole 15, the first recessed portion 11, and the second recessed portion 12, and the metal paste 86 is fired to obtain the metal member 16.

The metal paste 86 shrinks in the process of firing. Stress F1 to shrink acts in a direction from the center portion of the through hole 15 toward the first recessed portion 11 and the second recessed portion 12. Since the connection portion 19A between the through hole 15 and the first recessed portion 11 and the connection portion 19B between the through hole 15 and the second recessed portion 12 are rounded in cross-sectional view, the orientation of the stress F1 acting on the metal paste 86 in the through hole 15 can be dispersed.

The firing temperature can be in a range from 700° C. to 1200° C., and is preferably in a range from 750° C. to 1100° C., and particularly preferably in a range from 780° C. to 850° C. The firing atmosphere is preferably a vacuum atmosphere of 10⁻⁵ Pa or less or an Ar atmosphere of 99.9% or more.

### Polishing Metal Member

In S70 of polishing the metal member, the metal member 16 is polished to remove a part thereof. Here, the metal member 16 is polished so that the first flat surface portion 13 and the second flat surface portion 14 are exposed. The polishing is preferably performed such that the surface of the metal member 16 is parallel to the first flat surface portion 13 and the second flat surface portion 14 and the metal member 16 is flush with the first flat surface portion 13 and the second flat surface portion 14. At that time, a part of the first flat surface portion 13 and a part of the second flat surface portion 14 can be polished together with the metal member 16. The polishing can be performed by, for example, a grinding machine or a polishing machine.

### Forming Plating Layer

In S80 of forming the plating layer, the plating layer 17 is formed on the exposed surface of the metal member 16. The plating layer 17 can be formed by electroless plating. The plating can be performed through a mask. After forming the plating layer 17, the assembly 1P in which the plurality of ceramic sintered compact substrates 1 are aligned in the row direction and the column direction is formed.

### Performing Singulation

In S90 of performing singulation, the assembly 1P is cut and separated into the ceramic sintered compact substrates 1, which are separated pieces. The cutting lines SL1 and SL2 to be cut are positioned in a lattice shape on the ceramic substrate 10 in plan view. The cutting can be performed with, for example, a laser or a blade.

In the manufacturing method S1 for the ceramic sintered compact substrate having the above configuration, the orientation of the stress F1 acting on the metal paste 86 in the through hole 15 can be dispersed. Due to this, the stress at the center portion of the through hole 15 becomes smaller than that in a case in which the connection portions 19A and 19B are not rounded in cross-sectional view, and the division of the metal paste 86 inside the through hole 15 can be reduced.

By disposing the metal paste 86 in the first recessed portion 11 and the second recessed portion 12 formed of the patterns obtained by exposing and developing the dry films DF1 and DF2, it is possible to increase the accuracy of formation of the metal member 16. By forming the metal member 16 also on the first flat surface portion 13 and the second flat surface portion 14, it is possible to reduce deformation of the metal member 16 at the time of polishing.

The through hole 15 can be formed before S45 of forming the first recessed portion 11 and the second recessed portion 12. The through hole 15 can be formed penetrating through the dry films DF1 and DF2 and the ceramic substrate 10 after the dry films DF1 and DF2 are bonded, or can be formed after exposure and development.

### Ceramic Sintered Compact Substrate According to Second Embodiment

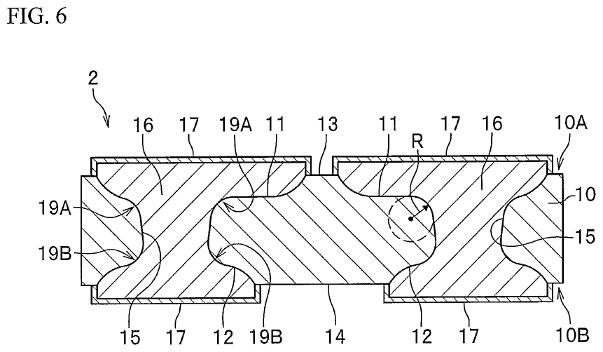

Subsequently, a ceramic sintered compact substrate 2 according to the second embodiment will be described with reference to FIG. 6. FIG. 6 is a schematic cross-sectional view illustrating the ceramic sintered compact substrate 2.

The ceramic sintered compact substrate 2 is different from the ceramic sintered compact substrate 1 in that the metal member 16 protrudes relative to the first flat surface portion 13 and the second flat surface portion 14 of the ceramic substrate 10. The plating layer 17 is provided also on a protruding lateral surface portion of the metal member 16. The ceramic sintered compact substrate 2 is the same as the ceramic sintered compact substrate 1 in the other points.

It is possible to increase the thickness of the ceramic sintered compact substrate 2 by making the metal member 16 protrude from the ceramic substrate 10, to adjust the thickness of the ceramic sintered compact substrate 2. A resin or the like having light reflectivity can be thickly disposed on the first flat surface portion 13 and the second flat surface portion 14 around the protruding metal member 16. Thus, for example, when the ceramic sintered compact substrate 2 is used in a light-emitting device, the light reflectance with respect to light of the light-emitting element can be increased, and light extraction efficiency of the light-emitting device can be improved.

### Method for Manufacturing Ceramic Sintered Compact Substrate According to Second Embodiment

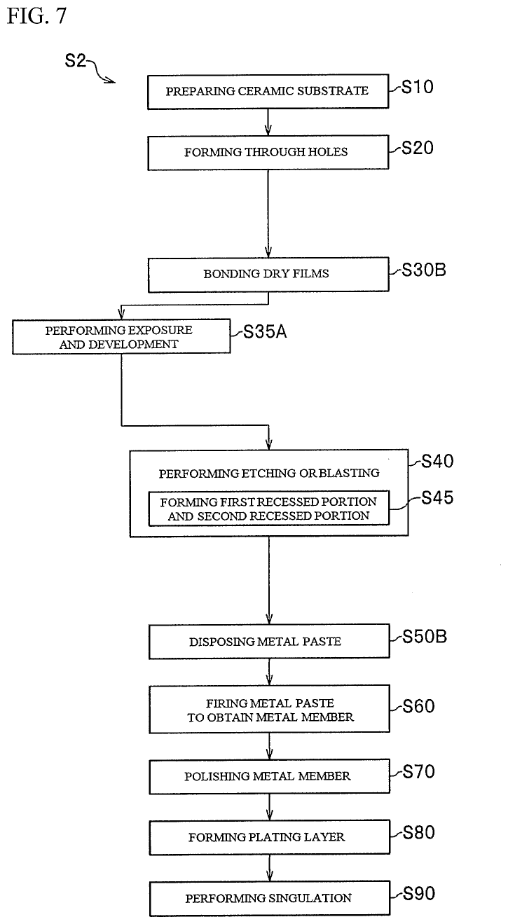

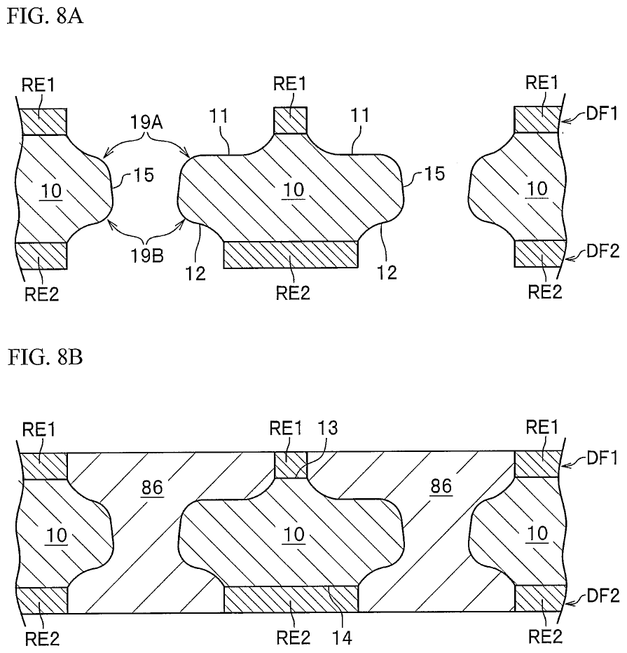

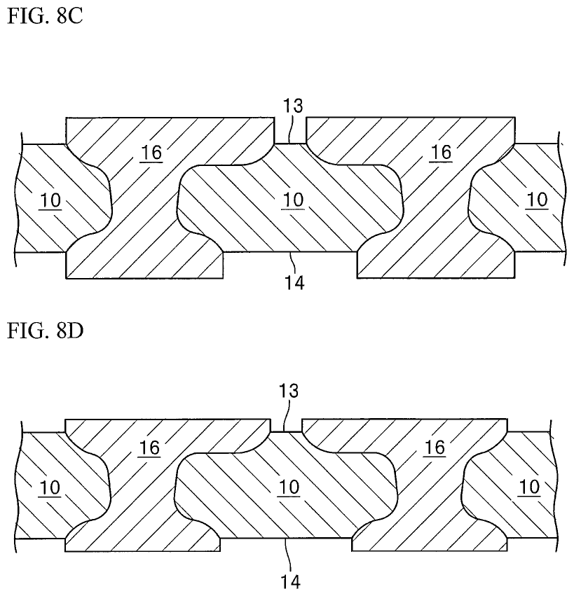

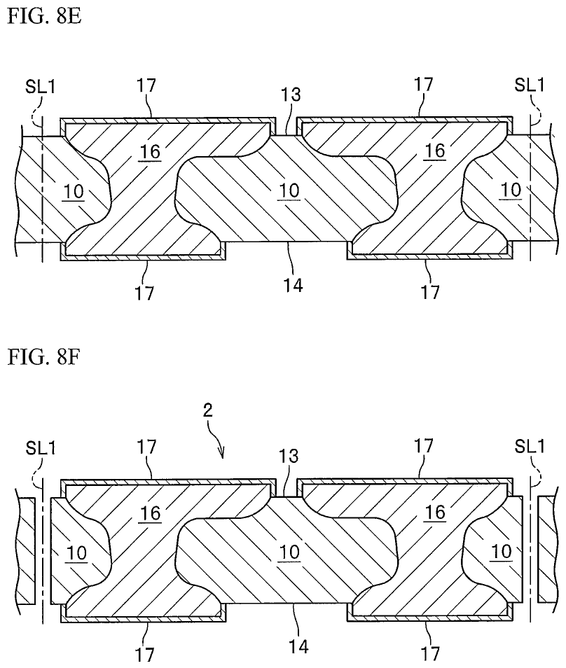

Subsequently, a manufacturing method S2 for the ceramic sintered compact substrate 2 according to the second embodiment will be described with reference to FIGS. 7 to 8F. FIG. 7 is a flowchart showing the manufacturing method S2 for the ceramic sintered compact substrate. FIG. 8A is a schematic cross-sectional view illustrating an etched or blasted state. FIG. 8B is a schematic cross-sectional view illustrating a state in which the metal paste 86 is disposed. FIG. 8C is a schematic cross-sectional view illustrating the metal member 16 obtained by firing. FIG. 8D is a schematic cross-sectional view illustrating a state in which the metal member 16 is polished. FIG. 8E is a schematic cross-sectional view illustrating a state in which the plating layer 17 is formed on the metal member 16. FIG. 8F is a schematic cross-sectional view illustrating the ceramic sintered compact substrate 2 obtained by singulation.

The manufacturing method S2 is different from the manufacturing method S1 in that S50A of peeling off the dry films is not performed before S50B of disposing the metal paste. Hereinafter, differences from the manufacturing method S1 will be described, starting from formation of the first recessed portion 11 and the second recessed portion 12 through S40 of performing etching or blasting.

In S50B of disposing the metal paste, the metal paste 86 is disposed in the first recessed portion 11 and the second recessed portion 12 in a state where the resists RE1 and RE2 are not removed. By disposing the metal paste 86 such that it is flush with the resists RE1 and RE2, it is possible for the metal paste 86 to have a thickness large enough that it protrudes from the first flat surface portion 13 and the second flat surface portion 14. When the metal paste 86 is disposed, the surfaces of the resists RE1 and RE2 opposite to the ceramic substrate 10 are exposed.

In S60 of firing the metal paste 86 to obtain the metal member, the metal paste 86 is fired to obtain the metal member 16. In this firing, the dry films DF1 and DF2 are decomposed, evaporated, and removed. This makes it possible to omit S50A of peeling off the dry films performed in the manufacturing method S1.

In S70 of polishing the metal member, as illustrated in FIGS. 8C and 8D, the metal member 16 is polished to remove a part thereof. Here, polishing is performed while adjusting the thickness of the metal member 16 protruding from each of the first flat surface portion 13 and the second flat surface portion 14. The thickness of the metal member 16 protruding from each of the first flat surface portion 13 and the second flat surface portion 14 can be, for example, in a range from 1 μm to 100 μm. The polishing can be performed with, for example, a polishing machine or a grinding machine as in the manufacturing method S1.

In S80 of forming the plating layer, as illustrated in FIG. 8E, the plating layer 17 is formed on the exposed surface of the metal member 16. The plating layer 17 can be formed by electroless plating as in the manufacturing method S1, and covers also the lateral surface portion of the metal member 16 protruding from the ceramic substrate 10. Then, in S90 of performing singulation, separation can be performed to obtain the ceramic sintered compact substrate 2.

The manufacturing method S2 for the ceramic sintered compact substrate allows formation of the metal member 16 into a shape protruding from the ceramic substrate 10, and can shorten the manufacturing process by omitting S50A of peeling off the dry films.

### Ceramic Sintered Compact Substrate According to Third Embodiment

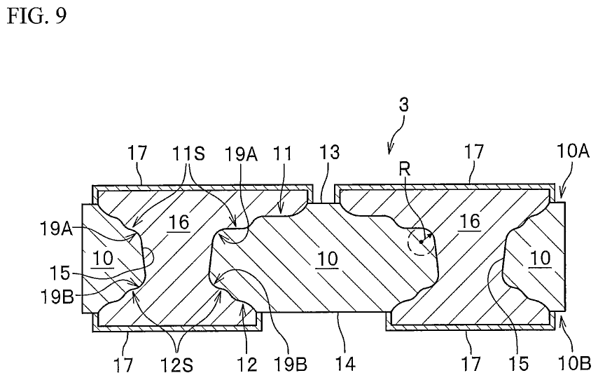

Subsequently, a ceramic sintered compact substrate 3 according to the third embodiment will be described with reference to FIG. 9. FIG. 9 is a schematic cross-sectional view illustrating the ceramic sintered compact substrate 3.

The ceramic sintered compact substrate 3 is different from the ceramic sintered compact substrate 2 in that the first recessed portion 11 and the second recessed portion 12 have step portions 11S and 12S around the through hole 15. The roundness of the connection portion between the through hole 15 and the inner surface defining the first recessed portion 11 and the connection portion between the through hole 15 and the inner surface defining the second recessed portion 12 is formed in the connection portion 19A between the through hole 15 and the step portion 11S and the connection portion 19B between the through hole 15 and the step portion 12S. The ceramic sintered compact substrate 3 is the same as the ceramic sintered compact substrate 2 in the other points. The step portion 11S and the step portion 12S are preferably connected by curved surfaces in the first recessed portion 11 and the second recessed portion 12.

In the ceramic sintered compact substrate 3, since the first recessed portion 11 and the second recessed portion 12 include the step portions 11S and 12S, it is possible to increase the contact area between the metal member 16 and the ceramic substrate 10, improve the heat dissipation, and further reduce peeling of the metal member 16.

The step portion can be provided only in one of the first recessed portion 11 and the second recessed portion 12.

### Method for Manufacturing Ceramic Sintered Compact Substrate According to Third Embodiment

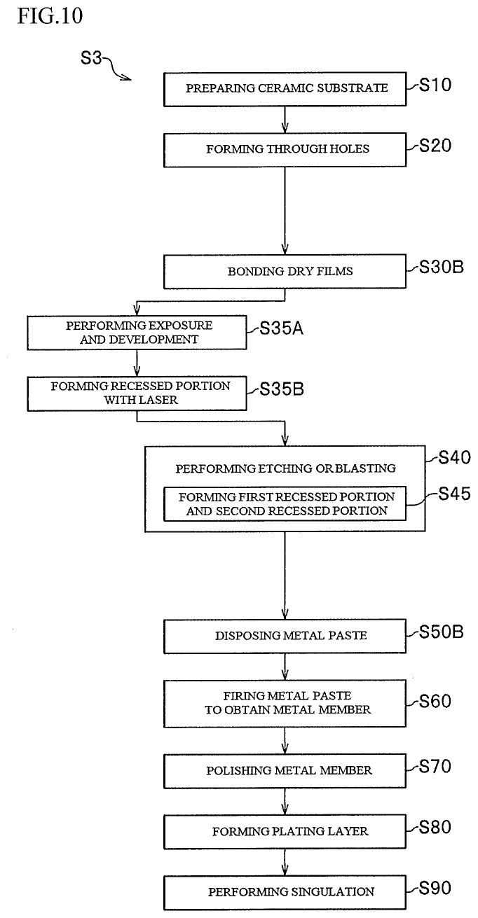

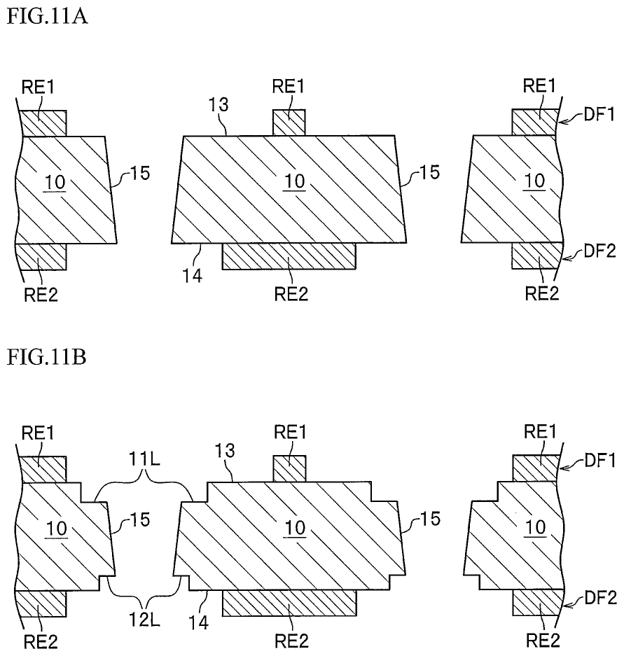

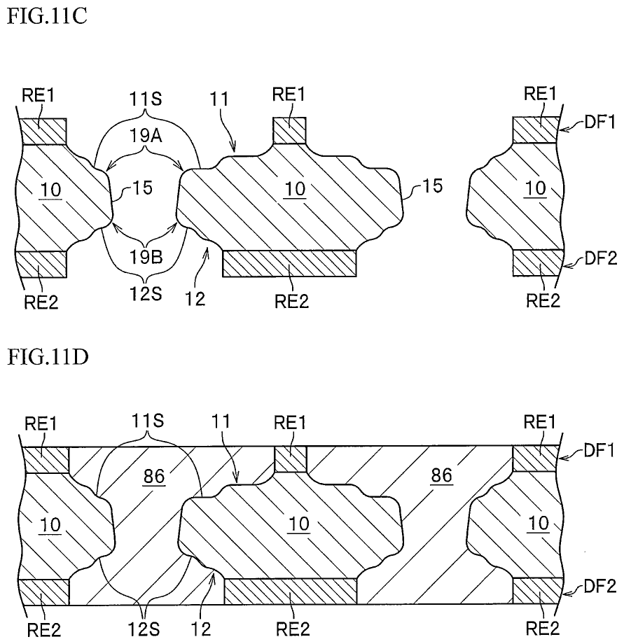

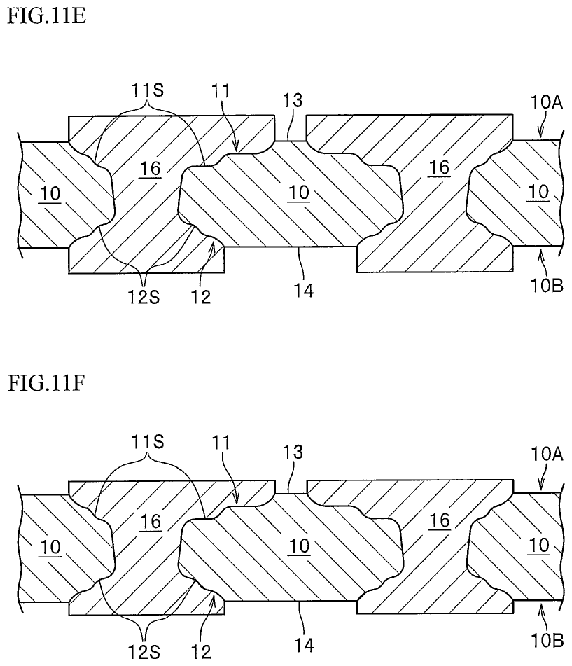

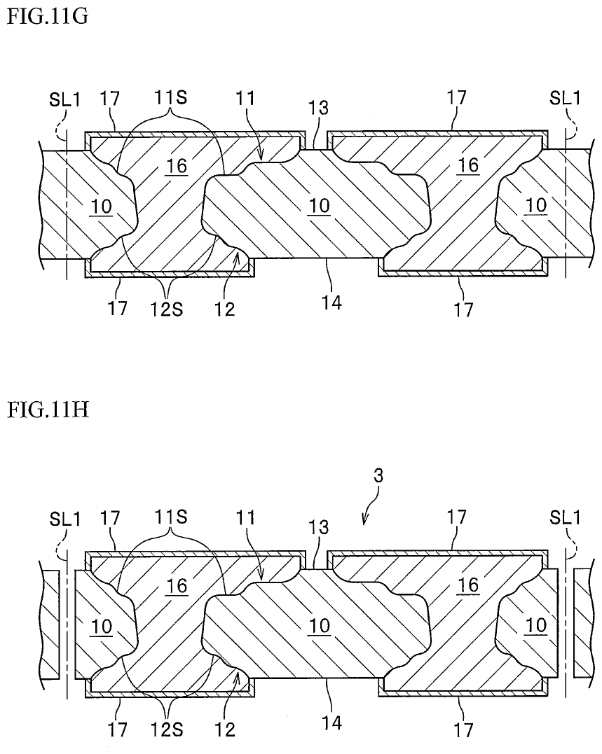

Subsequently, a manufacturing method S3 for the ceramic sintered compact substrate 3 according to the third embodiment will be described with reference to FIGS. 10 to 11H. FIG. 10 is a flowchart showing the manufacturing method S3 for the ceramic sintered compact substrate. FIG. 11A is a schematic cross-sectional view illustrating a state in which development of the dry films DF1 and DF2 is performed. FIG. 11B is a schematic cross-sectional view illustrating a state in which a recessed portion is formed with a laser. FIG. 11C is a schematic cross-sectional view illustrating an etched or blasted state. FIG. 11D is a schematic cross-sectional view illustrating a state in which the metal paste 86 is disposed. FIG. 11E is a schematic cross-sectional view illustrating the metal member 16 obtained by firing. FIG. 11F is a schematic cross-sectional view illustrating a state in which the metal member 16 is polished. FIG. 11G is a schematic cross-sectional view illustrating a state in which the plating layer 17 is formed on the metal member 16. FIG. 11H is a schematic cross-sectional view illustrating the ceramic sintered compact substrate 3 obtained by singulation.

The manufacturing method S3 is different from the manufacturing method S2 in performing S35B of forming a recessed portion with a laser before S40 of performing etching or blasting. Hereinafter, description will be given from formation of the resists RE1 and RE2 through S35A of performing exposure and development.

In S35B of forming recessed portions with a laser, recessed portions 11L and 12L are formed with laser processing at positions away from the resists RE1 and RE2 in the ceramic substrate 10 on which the resists RE1 and RE2 are formed. The recessed portions 11L and 12L each preferably surround the through hole 15 with an equal width in plan view. The depths of the recessed portions 11L and 12L from the first flat surface portion 13 and the second flat surface portion 14, respectively, can be, for example, in a range from 5 μm to 60 μm. As the laser, for example, a CO₂ laser can be used.

In S40 of performing etching or blasting, etching or blasting is performed on the ceramic substrate 10 in which the recessed portions 11L and 12L are formed. By performing etching or blasting, it is possible to form, based on the recessed portions 11L and 12L, the step portions 11S and 12S having a curved shape in cross-sectional view in the thickness direction of the ceramic substrate 10. The connection portions 19A and 19B that are rounded can be formed between the through hole 15 and the step portion 11S and between the through hole 15 and the step portion 12S, respectively.

In S50B of disposing the metal paste, the metal paste 86 is disposed in close contact also with the step portions 11S and 12S. Here, as in the manufacturing method S2, the metal paste 86 is disposed so as to expose the surfaces of the resists RE1 and RE2 opposite to the ceramic substrate 10.

In S60 of firing the metal paste to obtain a metal member, as in the manufacturing method S2, the metal paste 86 becomes the metal member 16, and the dry films DF1 and DF2 are removed. Subsequently, in S70 of polishing the metal member, the metal member 16 is polished while adjusting the thickness thereof, and in S80 of forming the plating layer, the plating layer 17 is formed on the surface including the lateral surface portion of the metal member 16 protruding from the ceramic substrate 10. Then, in S90 of performing singulation, separation can be performed to obtain the ceramic sintered compact substrate 3.

In S35B of forming a recessed portion with a laser, the recessed portion can be formed by the laser processing only in one of the first flat surface portion 13 and the second flat surface portion 14, and the step portion can be formed only in one of the first recessed portion 11 and the second recessed portion 12.

### Ceramic Sintered Compact Substrates of First Modification and Second Modification

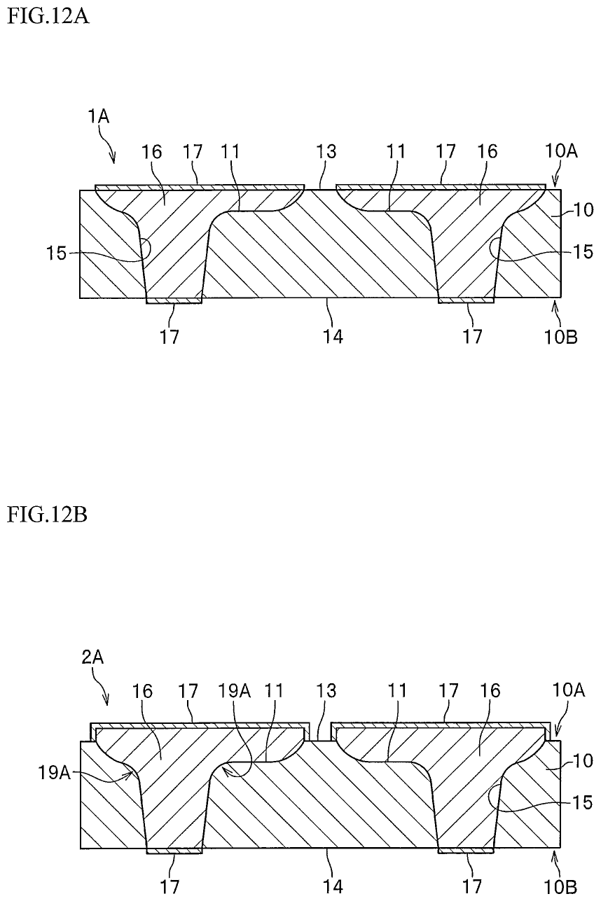

Subsequently, a ceramic sintered compact substrate 1A of the first modification and a ceramic sintered compact substrate 2A of the second modification will be described with reference to FIGS. 12A and 12B. FIG. 12A is a schematic cross-sectional view illustrating the ceramic sintered compact substrate 1A. FIG. 12B is a schematic cross-sectional view illustrating the ceramic sintered compact substrate 2A.

The ceramic sintered compact substrate 1A of the first modification is a modification not including the second recessed portion 12 of the ceramic sintered compact substrate 1 according to the first embodiment. The ceramic sintered compact substrate 2A of the second modification is a modification not including the second recessed portion 12 of the ceramic sintered compact substrate 2 according to the second embodiment. The ceramic sintered compact substrates 1A and 2A are different from the ceramic sintered compact substrates 1 and 2 in not including the second recessed portion 12, and are the same as the ceramic sintered compact substrates 1 and 2 in the other points.

In the ceramic sintered compact substrates 1A and 2A, the through hole 15 is not connected to the second recessed portion 12 but penetrates, with the hole diameter of the through hole 15, through the ceramic substrate 10 to the second flat surface portion 14 of the second surface 10B.

The ceramic sintered compact substrates 1A and 2A each include the ceramic substrate 10 having the first surface 10A and the second surface 10B opposite to the first surface 10A, is provided with the through hole 15 penetrating therethrough connecting the first surface 10A and the second surface 10B, and is provide with, in the first surface 10A, the first recessed portion 11 being larger in hole diameter than the through hole 15 and connected to the through hole 15, and the metal member 16 disposed in the first recessed portion 11 and the through hole 15. The connection portion between the through hole 15 and the inner surface defining the first recessed portion 11 is rounded in cross-sectional view in a thickness direction of the through hole 15.

### Method for Manufacturing Ceramic Sintered Compact Substrate of First Modification and Second Modification

Subsequently, a manufacturing method S1A for the ceramic sintered compact substrate 1A of the first modification and a manufacturing method S2A for the ceramic sintered compact substrate 2A of the second modification will be described.

The manufacturing method S1A can be performed similarly to the manufacturing method S1, and the manufacturing method S2A can be performed similarly to the manufacturing method S2. However, in S45 of forming the first recessed portion and the second recessed portion, the second recessed portion 12 is not formed but only the first recessed portion 11 is formed. The hole opening on the second surface 10B side of the through hole 15 is flush with the second surface 10B. In S30B of bonding dry films and S35A of performing exposure and the development, it is possible to omit bonding of the dry film DF2 to the second surface 10B and exposure and development of the dry film DF2. S50B of disposing the metal paste and the subsequent steps can be performed in a manner similar to that of the case of forming the second recessed portion 12.

The manufacturing method S1A for the ceramic sintered compact substrate 1A includes: S10 of preparing the ceramic substrate 10 having the first surface 10A and the second surface 10B opposite to the first surface 10A; bonding a dry film DF1 to the first surface 10A of the ceramic substrate 10; performing, through the mask PM1, exposure and development on the first surface 10A of the ceramic substrate 10 to which the dry film DF1 is bonded; etching or blasting the first surface 10A of the ceramic substrate 10 through the dry film DF1 formed into a predetermined pattern by performing the exposure and the development; forming the first recessed portion 11 recessed relative to the first flat surface portion 13 of the first surface 10A of the ceramic substrate 10 by performing the etching or the blasting; peeling off the dry film DF1 from the ceramic substrate 10; S50B of disposing the metal paste 86 in the first recessed portion 11 of the ceramic substrate 10; and S60 of firing the metal paste 86 disposed in the first recessed portion 11 to obtain the metal member. In the manufacturing method S1A, before the first recessed portion 11 is formed, the through hole 15 penetrating through the ceramic substrate 10 such that it connects the first surface 10A and the second surface 10B is formed at a position to be the first recessed portion 11, and in S50B of disposing the metal paste, the metal paste 86 is disposed in the first recessed portion 11 and the through hole 15. As in the case of forming the second recessed portion 12, the manufacturing method S1A can include, after S60 of firing the metal paste 86, S70 of polishing the metal member 16, S80 of forming the plating layer 17, and S90 of performing singulation.

### Ceramic Sintered Compact Substrates of Third Modification and Fourth Modification

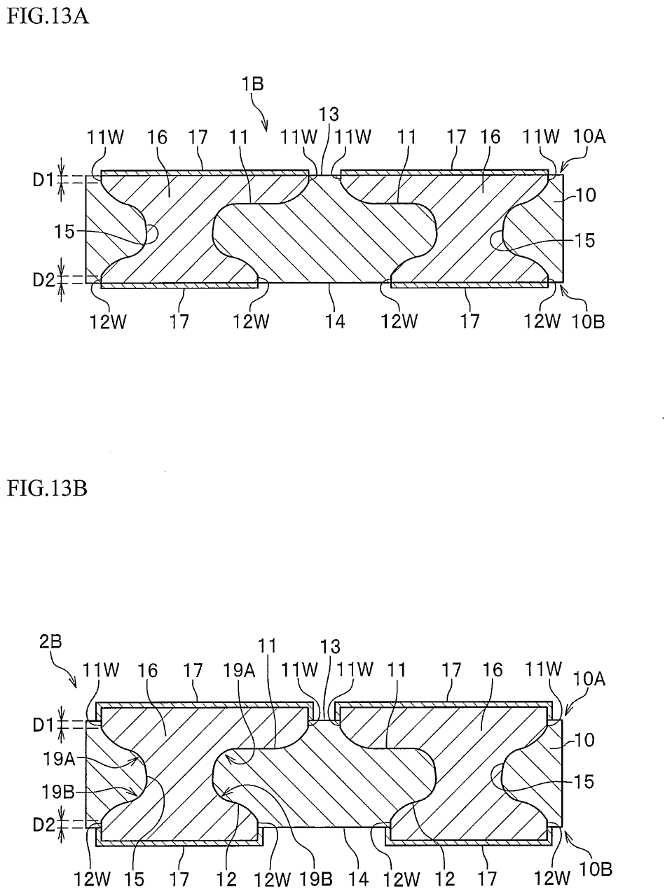

Subsequently, a ceramic sintered compact substrate 1B of the third modification and a ceramic sintered compact substrate 2B of the fourth modification will be described with reference to FIGS. 13A and 13B. FIG. 13A is a schematic cross-sectional view illustrating the ceramic sintered compact substrate 1B. FIG. 13B is a schematic cross-sectional view illustrating a ceramic sintered compact substrate 2B.

The ceramic sintered compact substrate 1B of the third modification is a modification of the ceramic sintered compact substrate 1 according to the first embodiment, and in cross-sectional view in the thickness direction of the ceramic sintered compact substrate, the inner lateral surface defining the first recessed portion 11 includes a linear portion 11W having a depth D1, and the inner lateral surface defining the second recessed portion 12 includes a linear portion 12W having a depth D2. The ceramic sintered compact substrate 1B is the same as the ceramic sintered compact substrate 1 in the other points.

The ceramic sintered compact substrate 2B of the fourth modification is a modification of the ceramic sintered compact substrate 2 according to the second embodiment, and in cross-sectional view in the thickness direction of the ceramic sintered compact substrate, the inner lateral surface defining the first recessed portion 11 includes the linear portion 11W having the depth D1, and the inner lateral surface defining the second recessed portion 12 includes the linear portion 12W having the depth D2. The ceramic sintered compact substrate 2B is the same as the ceramic sintered compact substrate 2 in the other points.

### Methods for Manufacturing Ceramic Sintered Compact Substrates of Third Modification and Fourth Modification

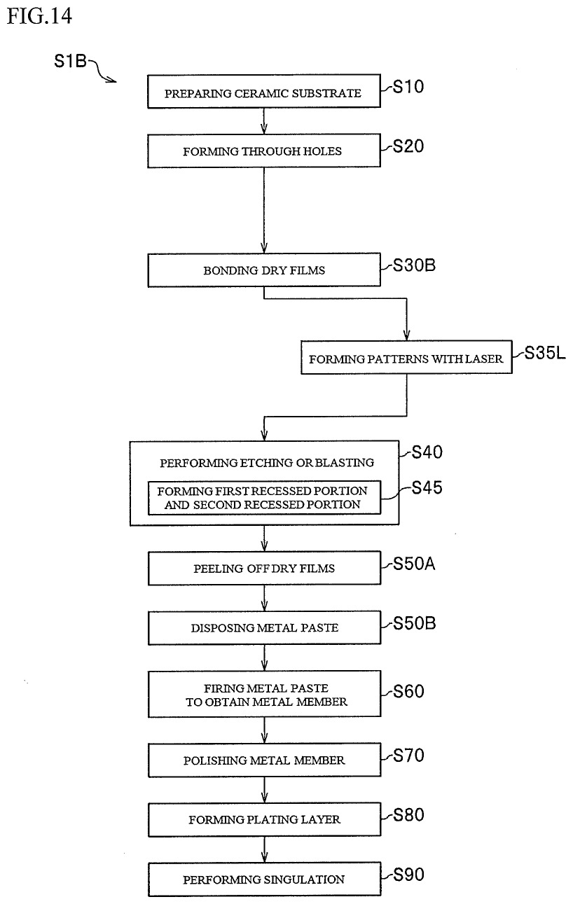

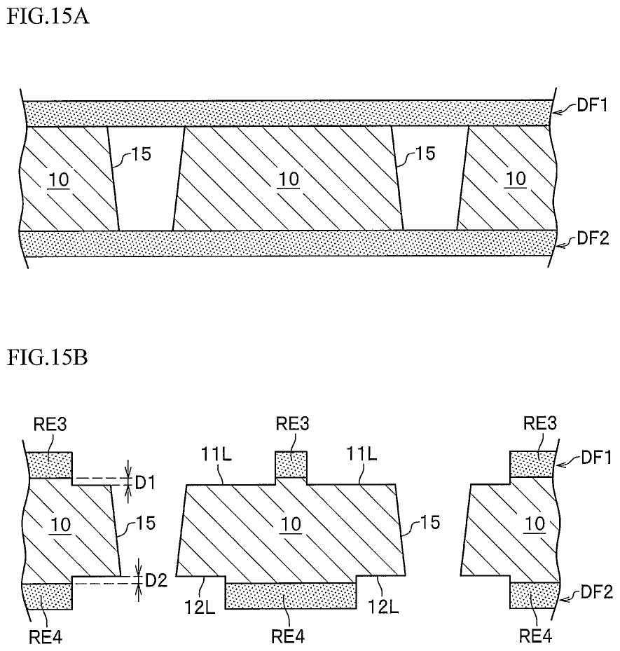

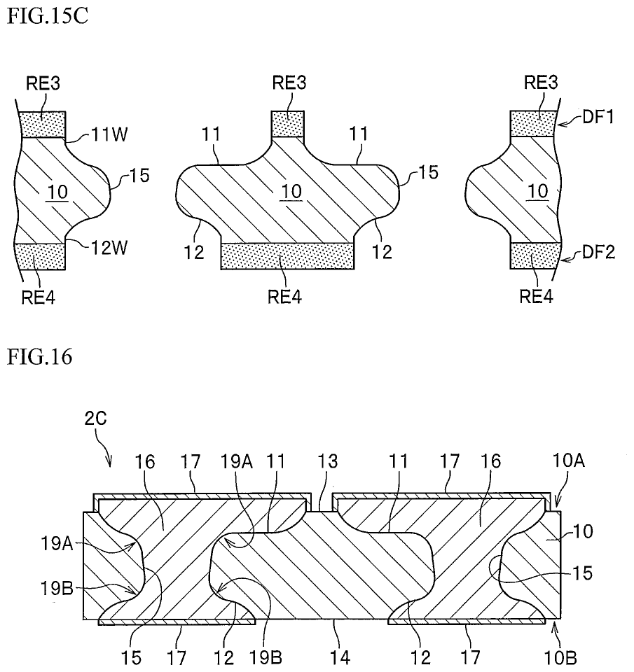

Subsequently, a manufacturing method S1B for the ceramic sintered compact substrate 1B of the third modification and a manufacturing method S2B for the ceramic sintered compact substrate 2B of the fourth modification will be described. FIG. 14 is a flowchart showing the manufacturing method S1B. FIG. 15A is a schematic cross-sectional view illustrating a state in which the dry films DF1 and DF2 are bonded. FIG. 15B is a schematic cross-sectional view illustrating a state in which patterns are formed with respect to the dry films DF1 and DF2 with a laser. FIG. 15C is a schematic cross-sectional view illustrating an etched or blasted state.

The manufacturing methods S1B and S2B are different from the manufacturing methods S1 and S2 in performing S35L of forming patterns with a laser instead of S35A of performing exposure and development. Regarding other points, the manufacturing method S1B for the third modification can be performed similarly to the manufacturing method S1, and the manufacturing method S2B for the fourth modification can be performed similarly to the manufacturing method S2. Hereinafter, with the manufacturing method S1B for the third modification as an example, differences from the manufacturing method S1 will be described, starting from performing S30B of bonding dry films to bond the dry films DF1 and DF2 to the ceramic substrate 10 in which the through hole 15 is formed.

In S35L of forming a pattern with a laser, patterns are formed with respect to the dry films DF1 and DF2 with laser processing. That is, resists RE3 and RE4 are formed, with laser processing, from the dry films DF1 and DF2 that are not exposed. Then, in the region from which the dry films DF1 and DF2 have been removed, it is possible to form the recessed portions 11L and 12L with laser processing by further removing a part of the ceramic substrate 10. The depths D1 and D2 of the recessed portions 11L and 12L can be adjusted with laser processing conditions.

Subsequently, in S40 of performing etching or blasting, the recessed portions 11L and 12L of the ceramic substrate 10 are etched or blasted using the resists RE3 and RE4 as resists. The first recessed portion 11 and the second recessed portion 12 are formed at deep positions by at least the depths D1 and D2, and respectively include the linear portions 11W and 12W in cross-sectional view in the thickness direction of the ceramic substrate 10. S50A of peeling the dry films and the subsequent steps can be performed in a manner similar to that of the manufacturing method S1.

In S35L of forming patterns with a laser, by performing laser processing so as not to form the recessed portions 11L and 12L or setting the depths D1 and D2 very shallow, it is possible to form the first recessed portion 11 and the second recessed portion 12 similar to those in the manufacturing methods S1 and S2.

In the manufacturing methods S1B and S2B, the manufacturing process can be simplified as compared with the case of performing exposure and development. The thickness of the metal paste 86 can be adjusted by the depths D1 and D2 of the recessed portions 11L and 12L formed with laser processing.

Etching or blasting can be performed only on one of the first surface 10A side and the second surface 10B side. It is possible to form, only on one side on which etching or blasting is performed, the first recessed portion 11 or the second recessed portion 12 having a curved surface and including the connection portions 19A and 19B with the through hole 15 that have a rounded shape in cross-sectional view. On the other side on which etching or blasting is not performed, subsequent to S35L of forming patterns with a laser, S50B of disposing the metal paste can be performed on the recessed portion 11L or the recessed portion 12L formed with laser processing, and subsequently, S60 of firing the metal paste to obtain the metal member and the subsequent steps can be similarly performed. Bonding of the dry film on the side on which etching or blasting is not performed can be omitted.

### Ceramic Sintered Compact Substrate of Fifth Modification

Subsequently, a ceramic sintered compact substrate 2C of the fifth modification will be described with reference to FIG. 16. FIG. 16 is a schematic cross-sectional view illustrating a ceramic sintered compact substrate 2C.

The ceramic sintered compact substrate 2C of the fifth modification is a modification in which the ceramic sintered compact substrate 1 according to the first embodiment and the ceramic sintered compact substrate 2 according to the second embodiment are combined. The ceramic sintered compact substrate 2C is different from the ceramic sintered compact substrate 2 in that the metal member 16 is flush with the second flat surface portion 14 on the second surface 10B side. For example, in cross-sectional view in the thickness direction of the ceramic sintered compact substrate 2, the metal member 16 disposed in the second recessed portion 12 is flush with the second flat surface portion 14 of the second surface 10B of the ceramic substrate 10. The ceramic sintered compact substrate 2C is the same as the ceramic sintered compact substrate 2 in the other points.

The metal member 16 can be flush with the first flat surface portion 13 on the first surface 10A side, and the metal member 16 can protrude from the second flat surface portion 14 on the second surface 10B side. That is, the metal member 16 can be flush with at least one of the first flat surface portion 13 and the second flat surface portion 14.

A manufacturing method for the ceramic sintered compact substrate 2C of the fifth modification is performed by combining the manufacturing method S1 for the ceramic sintered compact substrate 1 according to the first embodiment and the manufacturing method S2 for the ceramic sintered compact substrate 2 according to the second embodiment.

Steps up to and including S45 of forming the first recessed portion and the second recessed portion are performed in a manner similar to those of the manufacturing methods S1 and S2. Then, the manufacturing method S1 is performed on the side on which the metal member 16 does not protrude. That is, the metal paste 86 is disposed after peeling off the dry film from one of the first surface 10A and the second surface 10B. The manufacturing method S2 is performed on the side on which the metal member 16 protrudes. That is, the metal paste 86 is disposed without peeling off the dry film from the other of the first surface 10A and the second surface 10B. Steps after and including S60 of firing the metal paste 86 to obtain the metal member 16 can be performed in a manner similar to those of the manufacturing methods S1 and S2.

### Modification of Method for Manufacturing Ceramic Sintered Compact Substrate According to First Embodiment

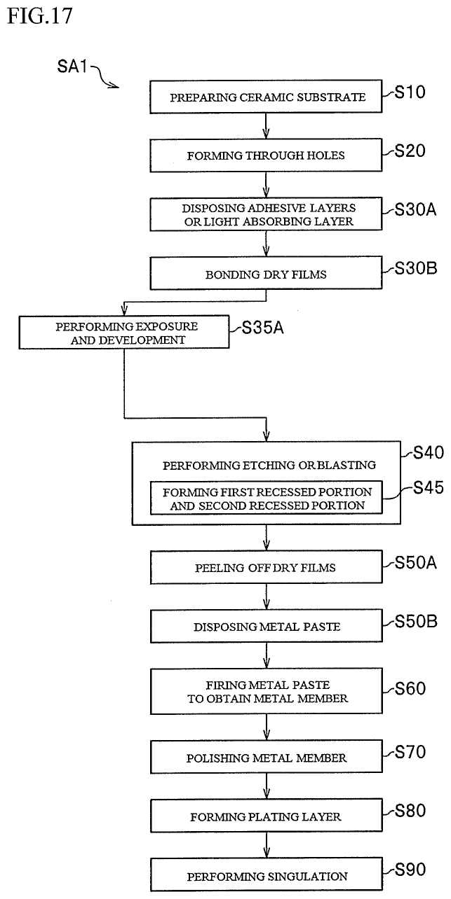

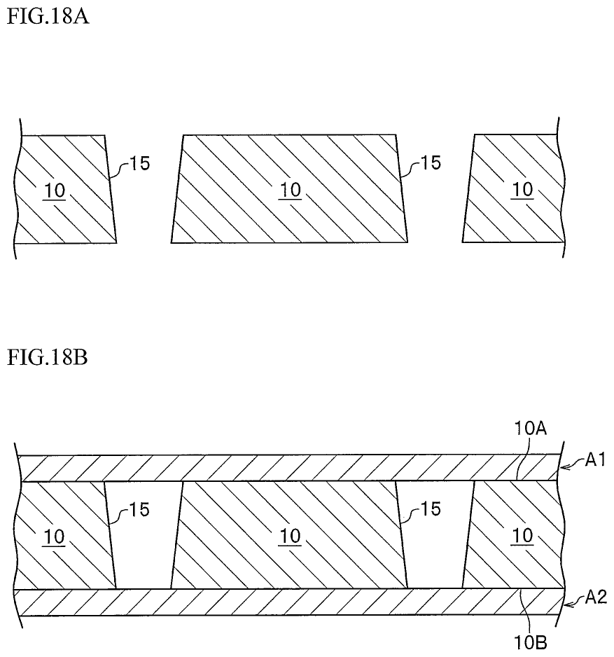

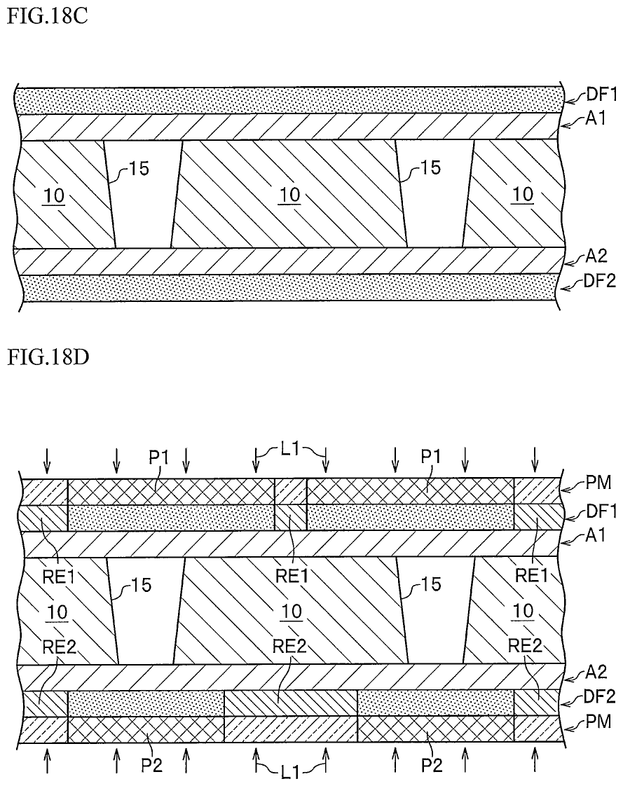

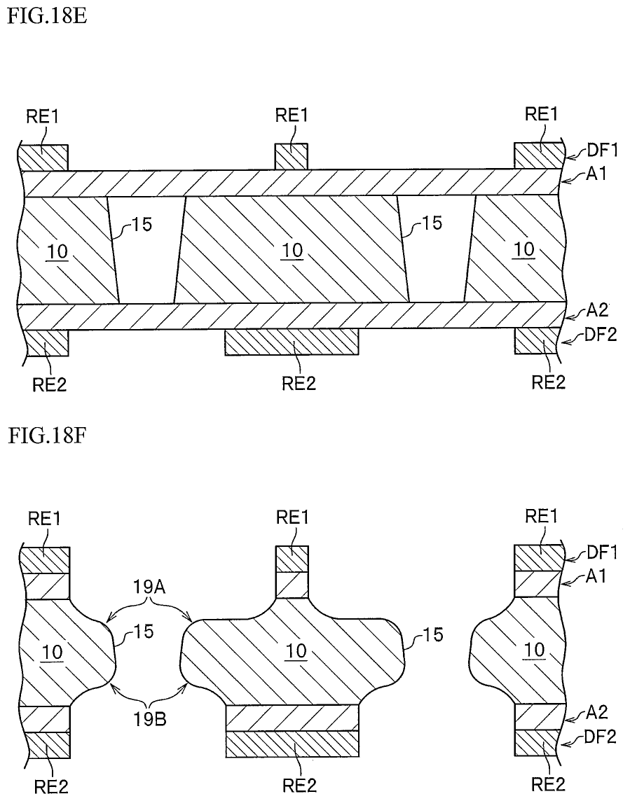

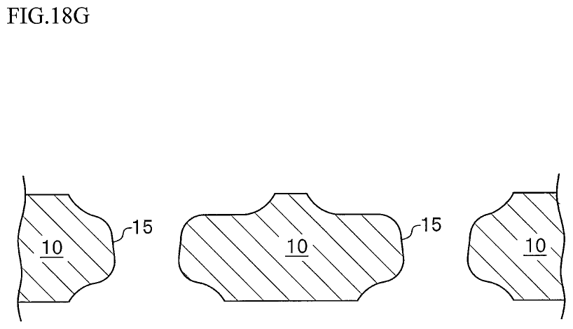

Subsequently, a manufacturing method SA1, which is a modification of the manufacturing method S1 for the ceramic sintered compact substrate 1, will be described with reference to FIGS. 17 to 18G. FIG. 17 is a flowchart showing the manufacturing method SA1. FIG. 18A is a schematic cross-sectional view illustrating a state in which the through hole 15 is formed. FIG. 18B is a schematic cross-sectional view illustrating a state in which the adhesive layers A1 and A2 are disposed. FIG. 18C is a schematic cross-sectional view illustrating a state in which the dry films DF1 and DF2 are bonded. FIG. 18D is a schematic cross-sectional view illustrating a state in which exposure of the dry films DF1 and DF2 is performed. FIG. 18E is a schematic cross-sectional view illustrating a state in which development of the dry films DF1 and DF2 is performed. FIG. 18F is a schematic cross-sectional view illustrating an etched or blasted state. FIG. 18G is a schematic cross-sectional view illustrating a state in which the dry films DF1 and DF2 and the adhesive layers A1 and A2 are peeled off.

In the manufacturing method SA1, before S30B of bonding dry films, S30A of disposing adhesive layers or a light absorbing layer is performed. Thus, the manufacturing method SA1 is different from the manufacturing method S1 relating to the adhesive layers A1 and A2 or the light absorbing layer. Hereinafter, differences from the manufacturing method S1 will be described, starting from formation of the through hole 15 in the ceramic substrate 10 by performing S20 of forming the through hole.

In S30A of disposing adhesive layers or a light absorbing layer, the adhesive layer A1 is disposed on the first surface 10A of the ceramic substrate 10, and the adhesive layer A2 is disposed on the second surface 10B. The adhesive layers A1 and A2 can contain a light absorbing member. Here, for example, acrylic, epoxy, urethane, ethyl cellulose, polyvinyl alcohol, silicone, or the like, which can be used as the light absorbing member, is used as the material of the adhesive layers A1 and A2.

In S30B of bonding dry films, the dry film DF1 is bonded to the adhesive layer A1, and the dry film DF2 is bonded to the adhesive layer A2. As in the manufacturing method S1, exposure and development are performed to form the resists RE1 and RE2 on the adhesive layers A1 and A2, respectively.

In S40 of performing etching or blasting, the adhesive layers A1 and A2 are also etched or blasted together with the ceramic substrate 10.

In S50A of peeling off the dry films, the adhesive layers A1 and A2 are removed together with the dry films DF1 and DF2. The adhesive layers A1 and A2 can be removed by, for example, blasting or dissolving in a solvent. Steps including and after S50B of disposing the metal paste can be performed in a manner similar to that of the manufacturing method S1.

The adhesive layers A1 and A2 can be replaced with a light absorbing layer. That is, before S30B of bonding dry films, the light absorbing layer can be disposed between at least one of the first surface 10A and the second surface 10B of the ceramic substrate 10 and the corresponding dry film. The light absorbing layer can be made of, for example, acrylic, epoxy, urethane, ethyl cellulose, polyvinyl alcohol, or the like, and can be treated similarly to the adhesive layers A1 and A2.

In the manufacturing method SA1, reflection of the light L1 by the ceramic substrate 10 at the time of exposure can be inhibited by the adhesive layers A1 and A2 or the light absorbing layer, and the accuracy of pattern formation of the dry films DF1 and DF2 can be increased.

As in the manufacturing method S1, the through hole 15 is formed before S45 of forming the first recessed portion 11 and the second recessed portion 12. The through hole 15 can be formed penetrating through the dry films DF1 and DF2, the adhesive layers A1 and A2, and the ceramic substrate 10 after the adhesive layers A1 and A2 or the light absorbing layer is disposed and the dry films DF1 and DF2 are bonded.

The adhesive layers or the light absorbing layer is disposed on the first surface 10A and the second surface 10B in a case of forming the first recessed portion 11 and the second recessed portion 12, and is disposed only on the first surface 10A in a case of forming only the first recessed portion 11. The adhesive layer or the light absorbing layer can be disposed only on one of the first surface 10A and the second surface 10B in a case of forming both the first recessed portion 11 and the second recessed portion 12.

### Modification of Method for Manufacturing Ceramic Sintered Compact Substrate According to Second Embodiment

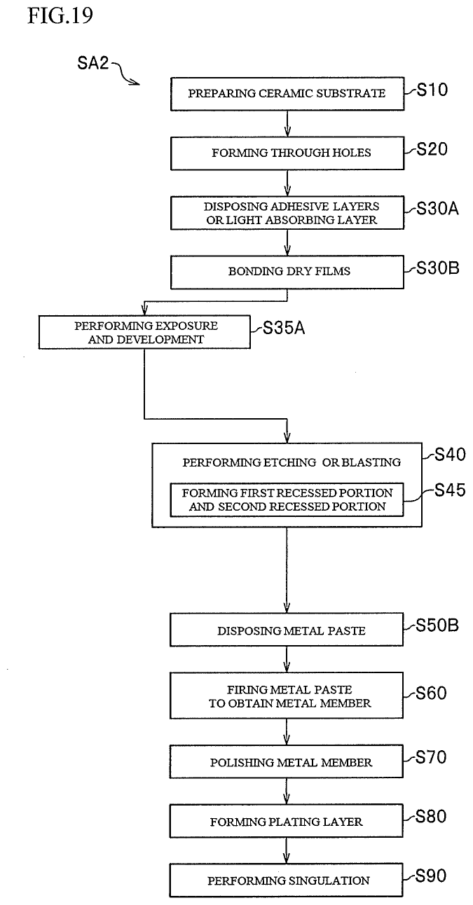

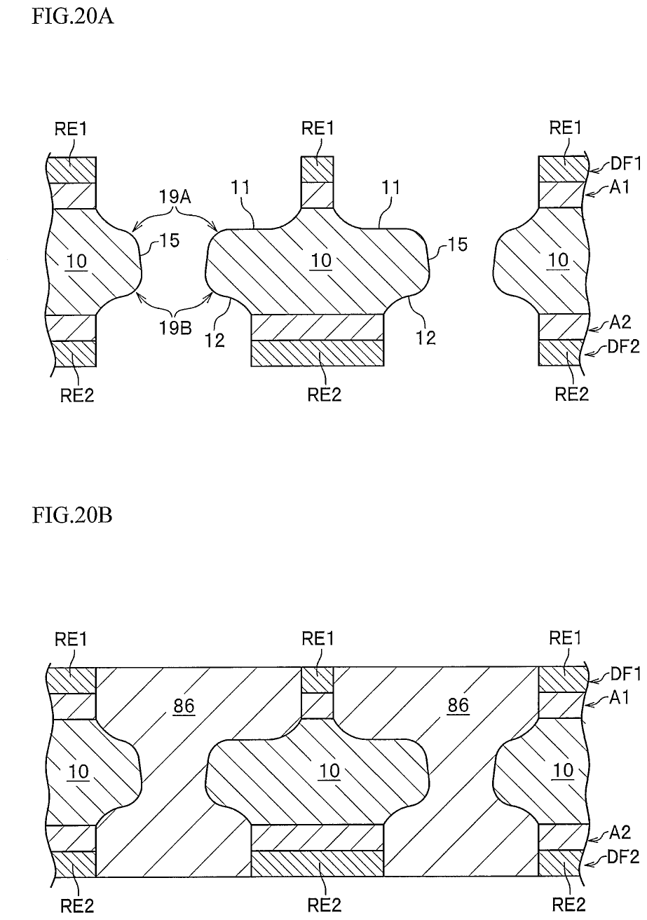

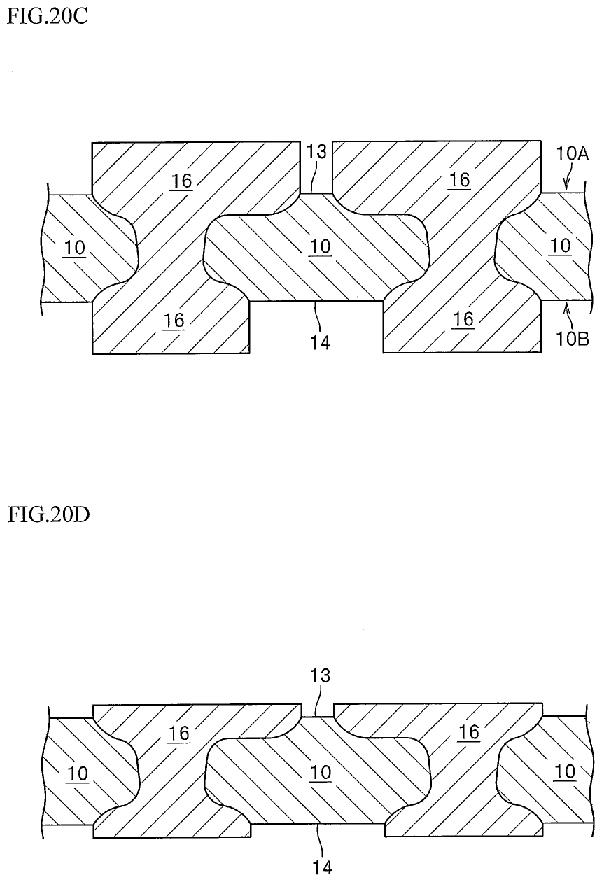

Subsequently, a manufacturing method SA2, which is a modification of the manufacturing method S2 for the ceramic sintered compact substrate 2, will be described with reference to FIGS. 19 to 20D. FIG. 19 is a flowchart showing the manufacturing method SA2. FIG. 20A is a schematic cross-sectional view illustrating an etched or blasted state. FIG. 20B is a schematic cross-sectional view illustrating a state in which the metal paste 86 is disposed. FIG. 20C is a schematic cross-sectional view illustrating the metal member 16 obtained by firing. FIG. 20D is a schematic cross-sectional view illustrating a state in which the metal member 16 is polished.

In the manufacturing method SA2, as in the manufacturing method SA1, before S30B of bonding dry films, S30A of disposing adhesive layers or a light absorbing layer is performed. Steps up to and including S40 of performing etching or blasting to form the first recessed portion 11 and the second recessed portion 12 can be performed in a manner similar to that of the manufacturing method SA1. Steps after S70 of polishing the metal member can be performed in a manner similar to that of the manufacturing method S2. Therefore, hereinafter, steps from S40 of performing etching or blasting to form the first recessed portion 11 and the second recessed portion 12 to S70 of polishing the metal member will be described.

In S40 of performing etching or blasting, as in the manufacturing method SA1, the adhesive layers A1 and A2 are also etched or blasted together with the ceramic substrate 10. Then, the metal paste 86 is disposed in the first recessed portion 11 and the second recessed portion 12 in a state where the dry films DF1 and DF2 and the adhesive layers A1 and A2 are not removed. Here, the metal paste 86 is disposed such that the surfaces of the resists RE1 and RE2 on the side opposite to the ceramic substrate 10 are exposed beyond the adhesive layers A1 and A2.

In S60 of firing the metal paste 86 to obtain the metal member 16, the metal paste 86, the adhesive layers A1 and A2, and the dry films DF1 and DF2 (resists RE1 and RE2) are fired. In this firing, the adhesive layers A1 and A2 and the dry films DF1 and DF2 are decomposed, evaporated, and removed. Thus, S50A of peeling off the dry films performed in the manufacturing method SA1 can be omitted.

In S70 of polishing the metal member, the metal member 16 is polished to remove a part thereof. Here, as in the manufacturing method S2, polishing is performed while adjusting the thickness of the metal member 16 protruding from the ceramic substrate 10. Steps after and including S80 of forming the plating layer can be performed in a manner similar to that of the manufacturing method S2. As in the manufacturing method SA1, in the manufacturing method SA2, the adhesive layers A1 and A2 can be replaced with a light absorbing layer.

The ceramic sintered compact substrate, the method for manufacturing the ceramic sintered compact substrate, and the modifications thereof can be not only the configurations described above but also combinations of any of the embodiments and any of the modifications.

### Light-Emitting Device

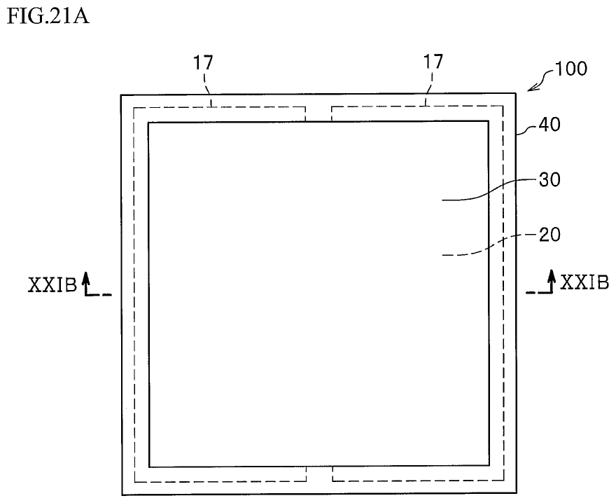

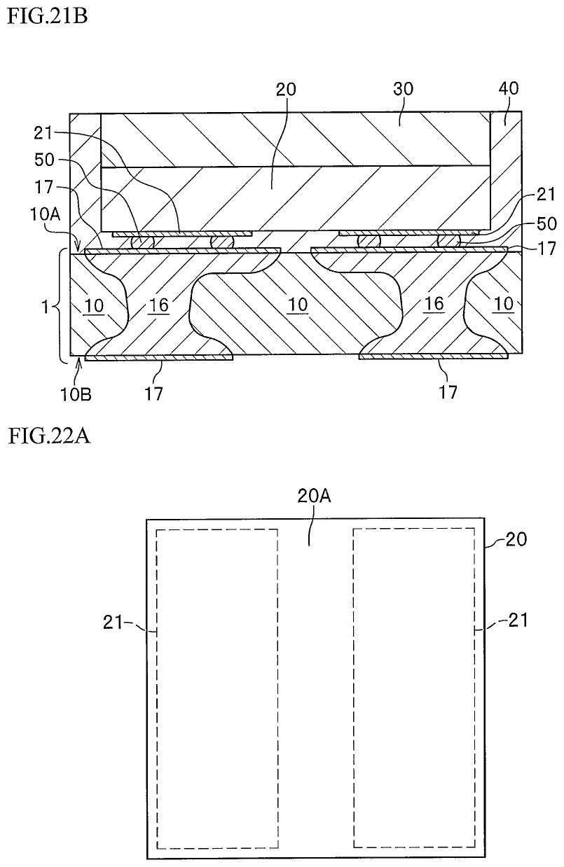

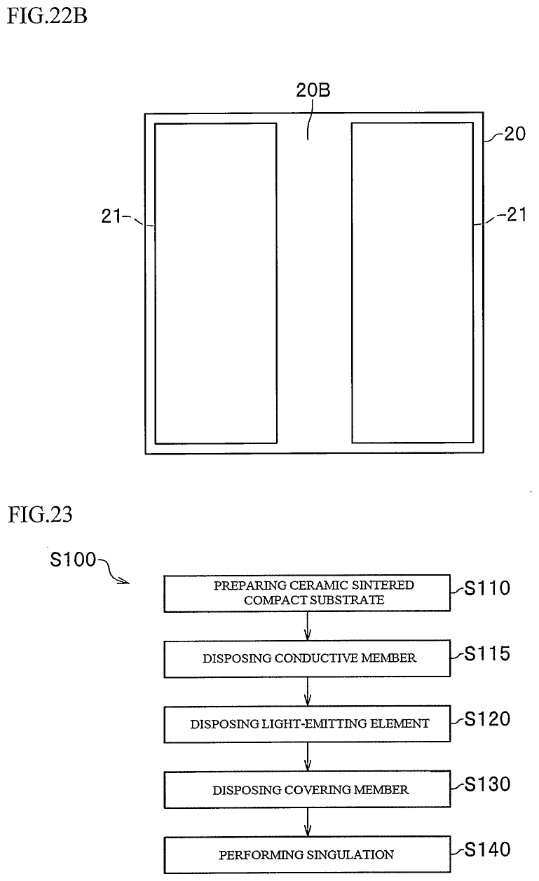

Subsequently, a light-emitting device 100 according to an embodiment will be described with reference to FIGS. 21A to 22B. FIG. 21A is a schematic plan view illustrating the light-emitting device 100. FIG. 21B is a schematic cross-sectional view illustrating a cross section taken along line XXIB-XXIB of FIG. 21A. FIG. 22A is a schematic plan view illustrating a light-emitting element 20. FIG. 22B is a schematic bottom view illustrating the light-emitting element 20.

The light-emitting device 100 includes a ceramic sintered compact substrate and the light-emitting element 20. The ceramic sintered compact substrate includes the ceramic substrate 10 and the metal member 16. The ceramic substrate 10 has the first surface 10A and the second surface 10B opposite to the first surface 10A, is provided with the through hole 15 penetrating therethrough connecting the first surface 10A and the second surface 10B, and is provided with, in the first surface 10A, the first recessed portion 11 being larger in hole diameter than the through hole 15 and connected to the through hole 15, and, in the second surface 10B, the second recessed portion 12 being larger in hole diameter than the through hole 15 and connected to the through hole 15. The metal member 16 is disposed in the first recessed portion 11, the second recessed portion 12, and the through hole 15. In cross-sectional view in the thickness direction of the through hole 15, at least one of the connection portion 19A between the through hole 15 and the inner surface defining the first recessed portion 11 and the connection portion 19B between the through hole 15 and the inner surface defining the second recessed portion 12 is rounded. The light-emitting element 20 is disposed over the metal member 16 and is directly or indirectly electrically connected to the metal member 16. Here, the light-emitting device 100 further includes a light-transmissive member 30 disposed on the upper surface of the light-emitting element 20, and a covering member 40 that covers the light-emitting element 20 and the light-transmissive member 30 with the upper surface of the light-transmissive member 30 being exposed.

The light-emitting device 100 includes one light-emitting element 20, for example. Each component of the light-emitting device 100 is described below.

### Ceramic Sintered Compact Substrate

The ceramic sintered compact substrate can be the ceramic sintered compact substrate 1 according to the first embodiment as an example, and the light-emitting element 20 is disposed thereover with the first surface 10A side as an upper surface. The metal member 16 and the plating layer 17 on the upper surface side have a size and a shape that allow an element electrode 21 of the light-emitting element 20 to be disposed.

### Light-Emitting Element

The light-emitting element 20 is a member that is supplied with power and emits light. The light-emitting element 20 has, for example, a rectangular shape. The light-emitting element 20 includes a semiconductor layered body, and here, a light-transmissive substrate of sapphire, gallium nitride, or the like is disposed on the upper surface side of the semiconductor layered body, and is provided with a pair of the element electrodes 21 on the lower surface side. For the semiconductor layered body, an arbitrary composition can be used in accordance with a desired emission wavelength, and for example, it is possible to use a nitride semiconductor (InₓAl_{y}Ga_{1-x-y}N, 0≤X, 0≤Y, X+Y≤1) or GaP, which can emit blue or green light, or GaAlAs or AlInGaP, which can emit red light. The size and the shape of the light-emitting element 20 can be appropriately selected in accordance with the purpose of use.

The pair of element electrodes 21 have a rectangular shape as an example, and are exposed on a lower surface 20B of the light-emitting element 20. The element electrode 21 can be formed of, for example, a single-layer film or a layered film of a metal such as gold, platinum, palladium, rhodium, nickel, tungsten, molybdenum, chromium, or titanium, or an alloy thereof.

Here, the element electrode 21 is connected to the metal member 16 through conductive members 50 and the plating layer 17. That is, the element electrode 21 is indirectly electrically connected to the metal member 16. The conductive member 50 can be, for example, a bump made of gold, solder, or the like. The element electrode 21 and the plating layer 17 can be connected by, for example, printing and disposing solder or the like on the entire electrode surface without providing the bump. The element electrode 21 can be directly electrically connected to the metal member 16 with solder or the like, not through the plating layer 17.

### Light-Transmissive Member

The light-transmissive member 30 protects an upper surface 20A of the light-emitting element 20 and is positioned on a light extraction surface of the light-emitting device 100. Here, the light-transmissive member 30 has a rectangular shape as an example, and has the same size and the same shape as those of the light-emitting element 20 in plan view. The light-transmissive member 30 can have a shape and a size that include the light-emitting element 20 in plan view.

The light-transmissive member 30 is made of, for example, a light-transmissive resin material, and an epoxy resin, a silicone resin, a resin in which these resins are mixed, or the like can be used. The light-transmissive member 30 can contain a phosphor, and for example, when the light-transmissive member 30 contains a phosphor that absorbs blue light from the light-emitting element 20 and emits yellow light, white light can be emitted from the light-emitting device 100. The light-transmissive member 30 can contain a plurality of types of phosphors, and for example, when the light-transmissive member 30 contains a phosphor that absorbs blue light from the light-emitting element 20 and emits green light and a phosphor that emits red light, white light can also be emitted from the light-emitting device 100.

The light-transmissive member 30 can further contain a light-emitting material such as a phosphor or a quantum dot. Examples of such a phosphor include yttrium-aluminum (gallium-doped) garnet activated with cerium, nitrogen-containing calcium (strontium) aluminosilicate activated with europium, potassium fluorosilicate activated with manganese, and a β-SiAlON phosphor.

Specific examples of the phosphor include yttrium-aluminum-garnet-based phosphors (e.g., (Y, Gd)₃(Al,Ga)₅ O₁₂:Ce), lutetium-aluminum-garnet-based phosphors (e.g., Lu₃(Al,Ga)₅O₁₂:Ce), terbium-aluminum-garnet-based phosphors (e.g., Tb₃(Al,Ga)₅O₁₂:Ce), CCA-based phosphors (e.g., Ca₁₀(PO₄)₆Cl₂:Eu), SAE-based phosphors (e.g., Sr₄Al₁₄O₂₅:Eu), chlorosilicate-based phosphors (e.g., Ca₈MgSi₄O₁₆Cl₂:Eu), silicate-based phosphors (e.g., (Ba,Sr,Ca,Mg)₂SiO₄:Eu), oxynitride-based phosphors such as β-SiAlON-based phosphors (e.g., (Si,Al)₃ (O,N)₄:Eu) and α-SiAlON-based phosphors (e.g., Ca(Si,Al)₁₂(O,N)₁₆:Eu), nitride-based phosphors such as LSN-based phosphors (e.g., (La,Y)₃Si₆N₁₁:Ce), BSESN-based phosphors (e.g., (Ba,Sr)₂Si₅N₈:Eu), SLA-based phosphors (e.g., SrLiAl₃N₄:Eu), CASN-based phosphors (e.g., CaAlSiN₃:Eu), and SCASN-based phosphors (e.g., (Sr,Ca)AlSiN₃:Eu), and fluoride-based phosphors such as KSF-based phosphors (e.g., K₂SiF₆:Mn), KSAF-based phosphors (e.g., K₂(Si₁₋ₓAlₓ)F₆₋ₓ:Mn, where x satisfies 0<x<1), and MGF-based phosphors (e.g., 3.5MgO·0.5MgF₂·GeO₂:Mn).

Examples of the quantum dots include quantum dots having a perovskite structure (for example, (Cs,FA,MA)(Pb,Sn)(F,Cl,Br,I)₃, where FA represents formamidinium and MA represents methylammonium), II-VI group quantum dots (for example, CdSe), III-V group quantum dots (for example, InP), quantum dots having a chalcopyrite structure (for example, (Ag,Cu)(In,Ga)(S,Se)₂), and the like.

### Covering Member

The covering member 40 is a member that is disposed on the upper surface of the ceramic sintered compact substrate 1 and covers and protects the lateral surfaces of the light-emitting element 20 and the light-transmissive member 30. The covering member 40 is disposed with the upper surface of the light-transmissive member 30 being exposed. The covering member 40 also covers the lateral surfaces of the element electrodes 21 and the conductive members 50 by entering between the light-emitting element 20 and the ceramic sintered compact substrate 1.

The covering member 40 can be formed of a resin having light reflectivity, light transmissivity, a light blocking property, or the like, any of these resins containing a light reflective substance, or the like. The covering member 40 preferably has at least any of light reflectivity and a light blocking property. Examples of the resin include a resin containing one or more of a silicone resin, a modified silicone resin, an epoxy resin, a modified epoxy resin, and an acrylic resin, and a hybrid resin. Examples of the light reflective substance include titanium oxide, silicon oxide, zirconium oxide, potassium titanate, aluminum oxide, aluminum nitride, boron nitride, and mullite. The covering member 40 can contain a phosphor, a diffusing material, a colorant, and the like.

In the light-emitting device 100, the heat dissipation against a temperature rise due to driving can be improved by the ceramic sintered compact substrate 1 in which the metal member 16 is embedded in the first recessed portion 11 and the second recessed portion 12. The ceramic sintered compact substrate 1 including the metal compound layer 18 can improve the reliability of bonding between the metal member 16 and the ceramic substrate 10 against thermal stress due to a temperature difference between the time of driving and the time of non-driving.

### Method for Manufacturing Light-Emitting Device

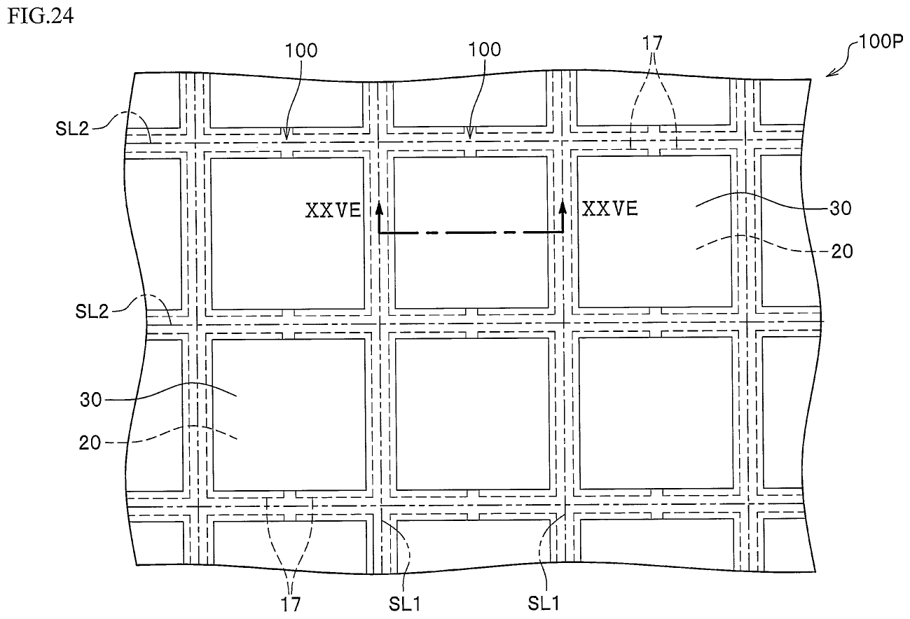

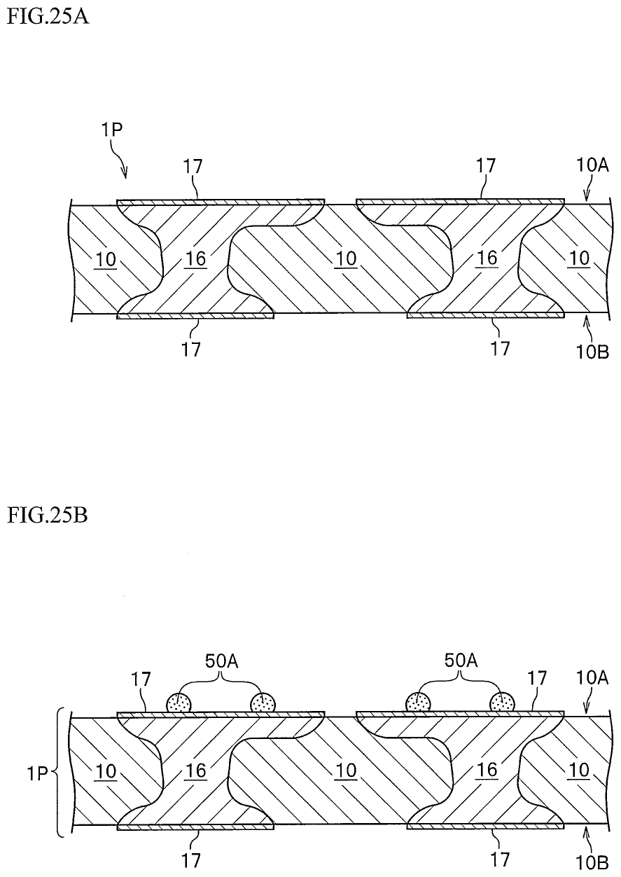

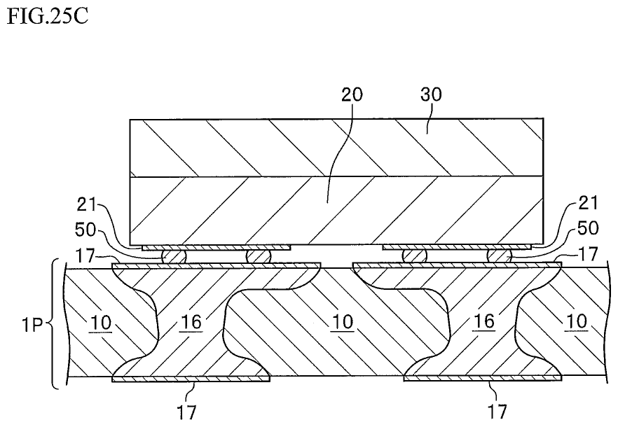

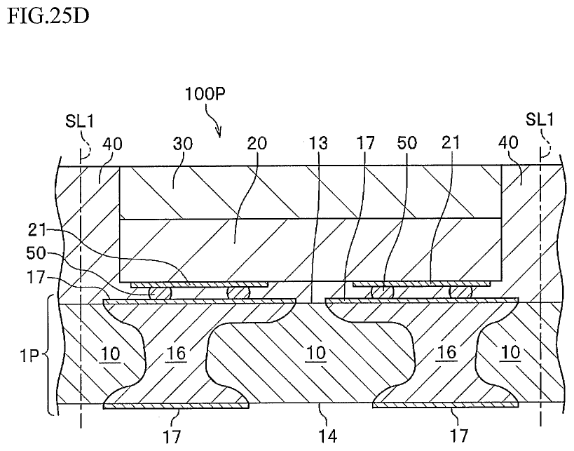

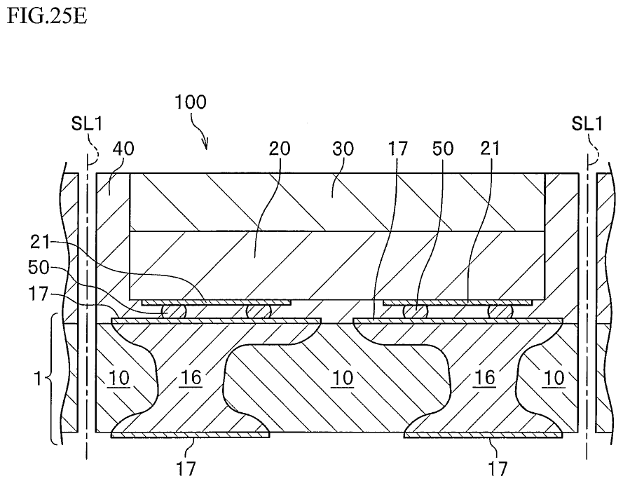

Subsequently, a manufacturing method S100 for a light-emitting device will be described with reference to FIGS. 23 to 25E. FIG. 23 is a flowchart showing the manufacturing method S100 for a light-emitting device. FIG. 24 is a schematic plan view illustrating an assembly 100P of the light-emitting devices 100 before singulation. FIG. 25A is a schematic cross-sectional view illustrating the assembly 1P of the ceramic sintered compact substrates 1 having been prepared. FIG. 25B is a schematic cross-sectional view illustrating a state in which conductive members 50A are disposed. FIG. 25C is a schematic cross-sectional view illustrating a state in which the light-emitting element 20 is disposed. FIG. 25D is a schematic cross-sectional view illustrating a state in which the covering member 40 is disposed. FIG. 25E is a schematic cross-sectional view illustrating the light-emitting device 100 obtained by singulation.

The manufacturing method S100 for a light-emitting device includes: S110 of preparing a ceramic sintered compact substrate that includes the ceramic substrate 10 having the first surface 10A and the second surface 10B opposite to the first surface 10A, being provided with the through hole 15 penetrating therethrough connecting the first surface 10A and the second surface 10B, and being provided with, in the first surface 10A, the first recessed portion 11 being larger in hole diameter than the through hole 15 and connected to the through hole 15, and, in the second surface 10B, the second recessed portion 12 being larger in hole diameter than the through hole 15 and connected to the through hole 15, and the metal member 16 disposed in the first recessed portion 11, the second recessed portion 12, and the through hole 15, and in which at least one of the connection portion 19A between the through hole 15 and the inner surface defining the first recessed portion 11 and the connection portion 19B between the through hole 15 and the inner surface defining the second recessed portion 12 is rounded in cross-sectional view in a thickness direction of the through hole 15; and S120 of disposing the light-emitting element 20 over the metal member 16. In S120 of disposing the light-emitting element, the metal member 16 and the light-emitting element 20 are directly or indirectly electrically connected to each other. Here, the manufacturing method further includes S115 of disposing the conductive members 50A, S130 of forming the covering member 40 covering the light-emitting element 20 and the light-transmissive member 30 in a state where the upper surface of the light-transmissive member 30 disposed on the upper surface of the light-emitting element 20 is exposed, and S140 of performing singulation. Each configuration of the manufacturing method S100 for a light-emitting device is described below.

In the description of the manufacturing method S100 for a light-emitting device, the assembly 100P in which a plurality of the light-emitting devices 100 are aligned in the row direction and the column direction is manufactured. By cutting the assembly 100P along cutting lines SL1 and SL2, it is possible to obtain the light-emitting devices 100.

### Preparing Ceramic Sintered Compact Substrate

In S110 of preparing the ceramic sintered compact substrate, for example, the assembly 1P of the ceramic sintered compact substrates 1 manufactured by the manufacturing method S1 for the ceramic sintered compact substrate is prepared. In the ceramic sintered compact substrate 1, the first surface 10A side on which the light-emitting element 20 is disposed is the upper surface. The metal member 16 and the plating layer 17 are formed in accordance with the size and disposition of the light-emitting element 20, the interval between the pair of element electrodes 21, and the like.

### Disposing Conductive Members

In S115 of disposing the conductive members, the conductive members 50A before bonding are disposed on the plating layer 17 on the upper surface side of the assembly 1P.

### Disposing Light-Emitting Element

In S120 of disposing the light-emitting element, the light-emitting elements 20 are disposed with the element electrodes 21 on the assembly 1P side. The light-emitting elements 20 are aligned in the row direction and the column direction over the assembly 1P. The element electrode 21 can be indirectly electrically connected to the metal member 16 through the conductive member 50 and the plating layer 17.

The element electrode 21 and the metal member 16 can be directly electrically connected to each other with solder or the like in a case of the ceramic sintered compact substrate not provided with the plating layer 17. In this case, S115 of disposing the conductive members can be omitted.

The light-transmissive member 30 is disposed in advance on the upper surface of the light-emitting element 20. The light-transmissive member 30 can be disposed by applying the unhardened material of the light-transmissive member 30 by, for example, potting, spraying, inkjetting, printing, or the like, and then hardening the material. For the light-transmissive member 30, a member formed into a sheet shape or a plate shape can be disposed on the upper surface of the light-emitting element 20 via an adhesive.

The light-transmissive member 30 can be disposed on the upper surface of the light-emitting element 20 after the light-emitting element 20 on which the light-transmissive member 30 is not disposed in advance is disposed over the ceramic sintered compact substrate.

### Disposing Covering Member

In S130 of disposing the covering member, the covering member 40 is disposed on the upper surface of the assembly 1P of the ceramic sintered compact substrate 1 such that the upper surface of the light-transmissive member 30 is exposed. The covering member 40 preferably covers the lateral surfaces of the light-emitting element 20 and the light-transmissive member 30, and preferably also covers the lower surface of the light-emitting element 20 and the lateral surface of the conductive member 50. The covering member 40 can be disposed, for example, by disposing a nozzle of a resin discharge device above the assembly 1P, applying an unhardened resin material by moving the nozzle while discharging the unhardened resin material from a tip of the nozzle, and then hardening the material. It is preferable that the covering member 40 is applied in a plurality of batches.

The upper surface of the covering member 40 is preferably flush with the upper surface of the light-transmissive member 30. The covering member 40 disposed between the adjacent light-emitting elements 20 and the adjacent light-transmissive members 30 can have an upper surface partially recessed or raised. By polishing, grinding, or the like the raised covering member 40, it is also possible to form the upper surface of the covering member 40 flush with the upper surface of the light-transmissive member 30. At this time, not only the upper surface of the covering member 40 but also an upper portion of the light-transmissive member 30 can be polished, ground, or the like.

After disposing the covering member 40, the assembly 100P in which the plurality of light-emitting devices 100 are aligned in the row direction and the column direction is formed.

### Performing Singulation

In S140 of performing singulation, the assembly 100P of the light-emitting devices is cut and separated into the light-emitting devices 100, which are separated pieces. The cutting lines SL1 and SL2 to be cut are positioned in a lattice shape on the covering member 40 in plan view. The cutting can be performed with, for example, a laser or a blade.

### Light-Emitting Devices According to First Modification and Second Modification

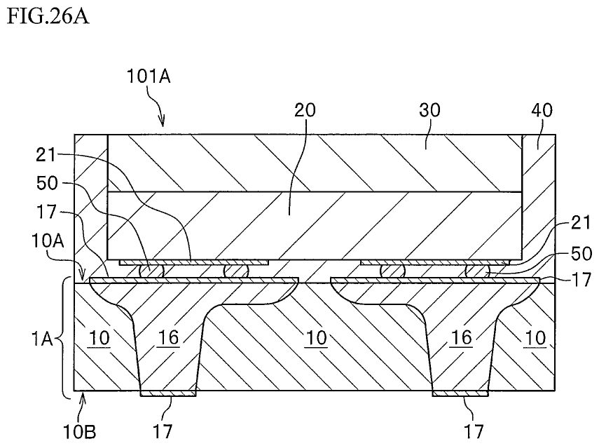

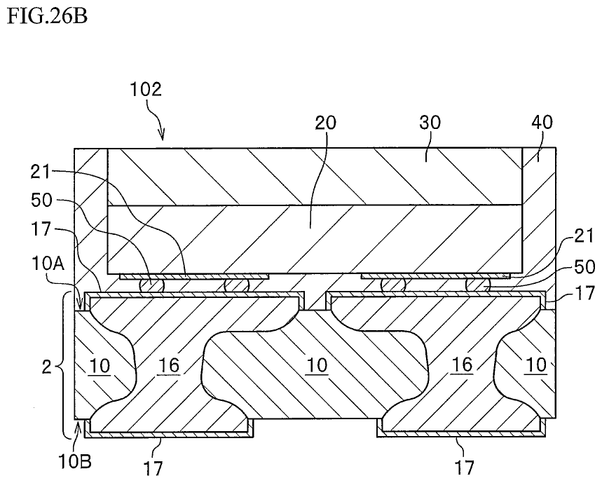

Subsequently, a light-emitting device 101A according to the first modification and a light-emitting device 102 according to the second modification will be described with reference to FIGS. 26A and 26B. FIG. 26A is a schematic cross-sectional view illustrating the light-emitting device 101A. FIG. 26B is a schematic cross-sectional view illustrating the light-emitting device 102.

The light-emitting devices 101A and 102 are different from the light- emitting device 100 in terms of the ceramic sintered compact substrate, and are the same as the light-emitting device 100 in the other points. The light-emitting device 101A uses the ceramic sintered compact substrate 1A according to the first modification. The light-emitting device 102 uses the ceramic sintered compact substrate 2 according to the second embodiment.

The light-emitting device 101A includes a ceramic sintered compact substrate and the light-emitting element 20. The ceramic sintered compact substrate includes the ceramic substrate 10 and the metal member 16. The ceramic substrate 10 has the first surface 10A and the second surface 10B opposite to the first surface 10A, is provided with the through hole 15 penetrating therethrough connecting the first surface 10A and the second surface 10B, and is provided with, in the first surface 10A, the first recessed portion 11 being larger in hole diameter than the through hole 15 and connected to the through hole 15. The metal member 16 is disposed in the first recessed portion 11 and the through hole 15. In cross-sectional view in the thickness direction of the through hole 15, the connection portion 19A between the through hole 15 and the inner surface defining the first recessed portion 11 is rounded. The light-emitting element 20 is disposed over the metal member 16 and is directly or indirectly electrically connected to the metal member 16.

The manufacturing method for the light-emitting device 101A includes: preparing a ceramic sintered compact substrate that includes the ceramic substrate 10 having the first surface 10A and the second surface 10B opposite to the first surface 10A, being provided with the through hole 15 penetrating therethrough connecting the first surface 10A and the second surface 10B, and being provided with, in the first surface 10A, the first recessed portion 11 being larger in hole diameter than the through hole 15 and connected to the through hole 15, and the metal member 16 disposed in the first recessed portion 11 and the through hole 15, and in which the connection portion 19A between the through hole 15 and the inner surface defining the first recessed portion 11 is rounded in cross-sectional view in a thickness direction of the through hole 15; and disposing the light-emitting element 20 over the metal member 16. In the disposing the light-emitting element 20, the metal member 16 and the light-emitting element 20 are directly or indirectly electrically connected to each other. The manufacturing method can further include disposing the conductive members 50A, disposing the light-transmissive member 30 on the upper surface of the light-emitting element 20, forming the covering member 40 covering the light-emitting element 20 and the light-transmissive member 30 with the upper surface of the light-transmissive member 30 being exposed, and performing singulation.

In the light-emitting device, a ceramic sintered compact substrate according to another embodiment or modification can also be used similarly. The manufacturing method for a light-emitting device can be performed similarly to the manufacturing method S100 for a light-emitting device by replacing the ceramic sintered compact substrate prepared in S110 of preparing a ceramic sintered compact substrate with that of another embodiment or modification.

1. A method for manufacturing a ceramic sintered compact substrate, the method comprising:
preparing a ceramic substrate having a first surface and a second surface opposite to the first surface;
bonding a dry film to the first surface of the ceramic substrate;
performing, through a mask, exposure and development on the first surface of the ceramic substrate to which the dry film is bonded;
etching or blasting the first surface of the ceramic substrate through the dry film formed into a predetermined pattern by performing the exposure and the development;
forming a first recessed portion recessed relative to a first flat surface portion of the first surface of the ceramic substrate by performing the etching or blasting;
peeling off the dry film from the ceramic substrate;
disposing a metal paste in the first recessed portion of the ceramic substrate; and
firing the metal paste disposed in the first recessed portion to obtain a metal member, wherein
before the first recessed portion is formed, a through hole penetrating through the ceramic substrate such that the through hole connects the first surface and the second surface of the ceramic substrate is formed at a position to be the first recessed portion, and
in the disposing of the metal paste, the metal paste is disposed in the first recessed portion and the through hole.

2. A method for manufacturing a ceramic sintered compact substrate, the method comprising:
preparing a ceramic substrate having a first surface and a second surface opposite to the first surface;
bonding a dry film to each of the first surface and the second surface of the ceramic substrate;
performing, through a mask, exposure and development on the first surface and the second surface of the ceramic substrate to which the dry films are bonded;
etching or blasting the first surface and the second surface of the ceramic substrate through the dry films formed into a predetermined pattern by performing the exposure and the development;
forming a first recessed portion recessed relative to a first flat surface portion of the first surface of the ceramic substrate and a second recessed portion recessed relative to a second flat surface portion of the second surface of the ceramic substrate by performing the etching or blasting;
peeling off the dry films from the ceramic substrate;
disposing a metal paste in the first recessed portion and the second recessed portion of the ceramic substrate; and
firing the metal paste disposed in the first recessed portion and the second recessed portion to obtain a metal member, wherein
before the first recessed portion and the second recessed portion are formed, a through hole penetrating through the ceramic substrate such that the through hole connects the first surface and the second surface of the ceramic substrate is formed at positions to be the first recessed portion and the second recessed portion, and
in the disposing of the metal paste, the metal paste is disposed in the first recessed portion, the second recessed portion, and the through hole.

3. The method for manufacturing a ceramic sintered compact substrate, according to claim 1, wherein
before the bonding of the dry film, an adhesive layer is disposed on the first surface of the ceramic substrate,
in the bonding of the dry film, the dry film is bonded to the adhesive layer, and
in the etching or blasting of the first surface, the adhesive layer is also etched or blasted.

4. The method for manufacturing a ceramic sintered compact substrate according to claim 3, wherein the adhesive layer contains a light absorbing member.

5. The method for manufacturing a ceramic sintered compact substrate according to claim 1, wherein before the bonding of the dry film, a light absorbing layer is disposed between the dry film and the first surface of the ceramic substrate.

6. The method for manufacturing a ceramic sintered compact substrate according to claim 1, wherein the through hole is formed before the dry film is bonded.

7. The method for manufacturing a ceramic sintered compact substrate according to claim 3, wherein the through hole is formed penetrating through the dry film, the adhesive layer, and the ceramic substrate after the adhesive layer is disposed and the dry film is bonded.

8. The method for manufacturing a ceramic sintered compact substrate according to claim 1, wherein before the peeling off of the dry film, the metal paste is disposed in the first recessed portion.

9. The method for manufacturing a ceramic sintered compact substrate according to claim 1, further comprising polishing the metal member after the metal member is obtained.

10. The method for manufacturing a ceramic sintered compact substrate according to claim 1, wherein a connection portion between the through hole and an inner surface defining the first recessed portion is made to have roundness by performing the etching or blasting.

11. The method for manufacturing a ceramic sintered compact substrate according to claim 1, wherein in the disposing of the metal paste, the metal paste contains at least active metal powder.

12. The method for manufacturing a ceramic sintered compact substrate according to claim 11, wherein the active metal powder is at least one selected from TiH₂, CeH₂, ZrH₂, and MgH₂.

13. The method for manufacturing a ceramic sintered compact substrate according to claim 1, wherein in the disposing of the metal paste, the metal paste contains at least one selected from Cu, Cr, Ni, Ag, Al, Zn, Sn, and an Ag—Cu alloy.

14. The method for manufacturing a ceramic sintered compact substrate according to claim 13, wherein in the disposing of the metal paste, the metal paste further contains an organic binder.

15. The method for manufacturing a ceramic sintered compact substrate according to claim 13, wherein in the disposing of the metal paste, the metal paste further contains a plurality of inorganic fillers other than a metal.

16. The method for manufacturing a ceramic sintered compact substrate according to claim 1, wherein in the firing of the metal paste to obtain a metal member, a firing temperature is in a range from 700° C. to 1200° C.

17. The method for manufacturing a ceramic sintered compact substrate according to claim 1, wherein in the firing of the metal paste to obtain a metal member, a firing atmosphere is a vacuum atmosphere or an Ar atmosphere of 99.9% or more.

18. The method for manufacturing a ceramic sintered compact substrate according to claim 1, wherein the through hole is formed having a diameter in a range from 0.05 mm to 0.5 mm.

19. A method for manufacturing a light-emitting device, the method comprising:
preparing a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole, and a metal member disposed in the first recessed portion, the second recessed portion, and the through hole, and in which at least one of a connection portion between the through hole and an inner surface defining the first recessed portion and a connection portion between the through hole and an inner surface defining the second recessed portion has roundness in cross-sectional view in a thickness direction of the through hole; and
disposing a light-emitting element over the metal member,
wherein in the disposing of the light-emitting element, the metal member and the light-emitting element are directly or indirectly electrically connected to each other.

20. A method for manufacturing a light-emitting device, the method comprising:
preparing a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and a metal member disposed in the first recessed portion and the through hole, and in which a connection portion between the through hole and an inner surface defining the first recessed portion has roundness in cross-sectional view in a thickness direction of the through hole; and
disposing a light-emitting element over the metal member,
wherein in the disposing of the light-emitting element, the metal member and the light-emitting element are directly or indirectly electrically connected with each other.

21. A ceramic sintered compact substrate comprising:
a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole; and
a metal member disposed in the first recessed portion and the through hole,
wherein a connection portion between the through hole and an inner surface defining the first recessed portion has roundness in cross-sectional view in a thickness direction of the through hole.

22. A ceramic sintered compact substrate comprising:
a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole; and
a metal member disposed in the first recessed portion, the second recessed portion, and the through hole,
wherein at least one of a connection portion between the through hole and an inner surface defining the first recessed portion and a connection portion between the through hole and an inner surface defining the second recessed portion has roundness in cross-sectional view in a thickness direction of the through hole.

23. The ceramic sintered compact substrate according to claim 21, wherein the roundness is annularly formed along the through hole.

24. The ceramic sintered compact substrate according to claim 21, wherein the roundness has a radius in a range from 2 μm to 110 μm in cross-sectional view in the thickness direction of the through hole.

25. The ceramic sintered compact substrate according to claim 21, wherein the first recessed portion is curved except for the through hole in cross-sectional view in a thickness direction of the ceramic sintered compact substrate.

26. The ceramic sintered compact substrate according to claim 21, wherein the inner surface defining the first recessed has an arithmetic mean roughness Ra in a range from 200 nm to 2 μm.

27. The ceramic sintered compact substrate according to claim 21, wherein in cross-sectional view in a thickness direction of the ceramic sintered compact substrate, a metal member disposed in the first recessed portion is flush with a first flat surface portion of the first surface of the ceramic substrate.

28. The ceramic sintered compact substrate according to claim 21, wherein a metal compound layer is present at a contact portion between the metal member and the ceramic substrate.

29. A light-emitting device comprising:
a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and, in the second surface, a second recessed portion being larger in hole diameter than the through hole and connected to the through hole, and a metal member disposed in the first recessed portion, the second recessed portion, and the through hole, and in which at least one of a connection portion between the through hole and an inner surface defining the first recessed portion and a connection portion between the through hole and an inner surface defining the second recessed portion has roundness in cross-sectional view in a thickness direction of the through hole; and
a light-emitting element that is disposed over the metal member,
wherein the light-emitting element is directly or indirectly electrically connected to the metal member.

30. A light-emitting device comprising:
a ceramic sintered compact substrate that includes a ceramic substrate having a first surface and a second surface opposite to the first surface, the ceramic substrate being provided with a through hole penetrating through the ceramic substrate such that the through hole connects the first surface and the second surface, and the ceramic substrate being provided with, in the first surface, a first recessed portion being larger in hole diameter than the through hole and connected to the through hole, and a metal member disposed in the first recessed portion and the through hole, and in which a connection portion between the through hole and an inner surface defining the first recessed portion has roundness in cross-sectional view in a thickness direction of the through hole; and
a light-emitting element that is disposed over the metal member,
wherein the light-emitting element is directly or indirectly electrically connected to the metal member.
